(19) United States
(12) Patent Application Publication
(10) Pub. No.: US 2024/0355575 A1
(43) Pub. Date: Oct. 24, 2024

(54) BEAM MANIPULATOR IN CHARGED PARTICLE-BEAM APPARATUS

(71) Applicant: ASML NETHERLANDS B.V., Veldhoven (NL)

(72) Inventors: German AKSENOV, Delft (NL); Vincent Claude BEUGIN, Nootdorp (NL); Pieter Lucas BRANDT, Son (NL)

(73) Assignee: ASML NETHERLANDS B.V., Veldhoven (NL)

(21) Appl. No.: 18/759,499

(22) Filed: Jun. 28, 2024

Related U.S. Application Data
(63) Continuation of application No. PCT/EP2022/083699, filed on Nov. 29, 2022.

(30) Foreign Application Priority Data
Dec. 31, 2021 (EP) 21218484.0

(51) Int. Cl. H01J 37/147; H01J 37/28

(52) U.S. Cl. CPC H01J 37/1472; H01J 37/28

(57) ABSTRACT

Disclosed herein is a manipulator or an array of manipulator. A manipulator manipulates a charged particle beam in a projection system. The manipulator comprising a substrate with major surfaces and a through-passage between associated apertures in the major surfaces. The through passage configured for passage of a path of a charged particle beam. An inner wall of the through-passage between the major surfaces comprises a plurality of electrodes configured to manipulate the charged particle beam. Each electrode comprises doped substrate. The through-passage comprises recesses that extend away from the path of the charged particle beam. Each recess defines a gap between the adjacent electrodes and further comprising an electrically insulating region between the adjacent electrodes. The recesses extend behind at least one of the adjacent electrodes relative to the path of the charged particle beam and comprising at least part of the electrically insulating region.

### CROSS-REFERENCE TO RELATED APPLICATION

This application claims priority of International application PCT/EP2022/083699, filed on 29 Nov. 2022, which claims priority of EP application Ser. No. 21/218,484.0, filed on 31 Dec. 2021. These applications are incorporated herein by reference in their entireties.

### FIELD

The embodiments provided herein generally relate to a charged particle beam illumination apparatus, and more particularly to a charged particle beam manipulator in a charged particle beam illumination apparatus.

### BACKGROUND

When manufacturing semiconductor integrated circuit (IC) chips, undesired pattern defects, as a consequence of, for example, optical effects and incidental particles, inevitably occur on a substrate (i.e. wafer) or a mask during the fabrication processes, thereby reducing the yield. Monitoring the extent of the undesired pattern defects is therefore an important process in the manufacture of IC chips. More generally, the inspection and/or measurement of a surface of a substrate, or other object/material, is an import process during and/or after its manufacture.

Pattern inspection tools with a charged particle beam have been used to inspect objects, for example to detect pattern defects. These tools typically use electron microscopy techniques, such as a scanning electron microscope (SEM). In a SEM, a primary electron beam of electrons at a relatively high energy is targeted with a final deceleration step in order to land on a sample at a relatively low landing energy. The beam of electrons is focused as a probing spot on the sample. The interactions between the material structure at the probing spot and the landing electrons from the beam of electrons cause electrons to be emitted from the surface, such as secondary electrons, backscattered electrons, or Auger electrons. The generated secondary electrons may be emitted from the material structure of the sample. By scanning the primary electron beam as the probing spot over the sample surface, secondary electrons can be emitted across the surface of the sample. By collecting these emitted secondary electrons from the sample surface, a pattern inspection tool may obtain an image representing characteristics of the material structure of the surface of the sample.

Another application for a charged particle beam is lithography. The charged particle beam reacts with a resist layer on the surface of a substrate. A desired pattern in the resist can be created by controlling the locations on the resist layer that the charged particle beam is directed towards.

There is a general need to improve the generation of a charged particle beam for use in electron microscopy as well as for other applications, such as lithography.

### SUMMARY

The embodiments provided herein disclose a charged particle beam illumination apparatus. The charged particle beam illumination apparatus may be used to generate a multi-beam of charged particles. The charged particle beam illumination apparatus may be comprised within an inspection apparatus or a lithography apparatus.

According to some embodiments of the present disclosure, there is a manipulator for manipulating a charged particle beam, the manipulator comprising a substrate with major surfaces and a through-passage that defines associated apertures of the ends of the through-passage in the major surfaces, the through passage configured for passage of a path of a charged particle beam, an inner wall of the through-passage between the major surfaces comprising a plurality of electrodes configured to manipulate the charged particle beam, each electrode comprising doped substrate, the through-passage further comprising recesses that extends away from the path of the charged particle beam for isolating individual or adjacent electrodes, each recess defining a gap between the adjacent electrodes and further comprising an electrically insulating region between the adjacent electrodes wherein the recess extends behind at least one of the adjacent electrodes relative to the path of the charged particle beam and comprising at least part of the electrically insulating region.

According to some embodiments of the present disclosure, there is a manipulator array for manipulating a plurality of charged particle beams along corresponding to a manipulator of the manipulator array, the manipulator array comprising a substrate with major surfaces and a plurality of manipulators arrayed in an array, each manipulator through which is defined a through-passage that defines associated apertures of the end of the through-passage in the major surfaces, the through passage configured for passage of a path of a charged particle sub-beam, an inner wall of the through-passage between the major surfaces comprising a plurality of electrodes configured to manipulate the charged particle beam, each electrode comprising doped substrate, the through-passage further defining a plurality of recesses each between adjoining electrodes and that extends away from the path of the charged particle sub-beam for isolating the adjoining electrodes, each recess being between the adjacent electrodes and further comprising an electrically insulating region between the adjacent electrodes, wherein the recess extends behind at least one of the adjacent electrodes relative to the path of the charged particle sub-beam and comprising at least part of the electrically insulating region.

Other advantages of the embodiments of the present disclosure will become apparent from the following description taken in conjunction with the accompanying drawings wherein are set forth, by way of illustration and example, certain embodiments of the present disclosure.

### BRIEF DESCRIPTION OF FIGURES

The above and other aspects of the present disclosure will become more apparent from the description of exemplary embodiments, taken in conjunction with the accompanying drawings.

FIG. 1 is a schematic diagram illustrating an exemplary charged particle beam inspection apparatus.

FIG. 2 is a schematic diagram illustrating an exemplary multi-beam apparatus that is part of the exemplary charged particle beam inspection apparatus of FIG. 1.

FIG. 3A is a schematic diagram of exemplary multi-beam apparatus illustrating an exemplary configuration of source conversion unit of the exemplary charged particle beam inspection apparatus of FIG. 1.

FIG. 3B is a schematic diagram of exemplary multi electrode structure array with a 3×3 configuration that is part of exemplary source conversion unit of FIG. 3A.

FIG. 4 is a schematic plan view of an exemplary beam manipulator array, consistent with embodiments of the prior art.

FIG. 5 is a schematic cross-sectional perspective view of the beam manipulator of the beam manipulator array of FIG. 4, consistent with embodiments of the prior art.

FIGS. 6A, 6B, 6C and 6D are schematic plan views of different arrangements of insulator formed in a substrate as well as openings formed within the substrate, consistent with embodiments of the present disclosure.

FIGS. 7A, 7B, 7C, 7D and 7E each show a slot arrangement between adjacent electrodes of beam manipulators, consistent with embodiments of the present disclosure.

FIGS. 8A and 8B, each show a slot arrangement between adjacent electrodes of a beam manipulator, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims.

The reduction of the physical size of devices, and enhancement of the computing power of electronic devices may be accomplished by significantly increasing the packing density of circuit components such as transistors, capacitors, diodes, etc. on an IC chip. This has been enabled by increased resolution enabling yet smaller structures to be made. For example, an IC chip of a smart phone, which is the size of a thumbnail and available in, or earlier than, 2019, may include over 2 billion transistors, the size of each transistor being less than 1/1000th of a human hair. Thus, it is not surprising that semiconductor IC manufacturing is a complex and time-consuming process, with hundreds of individual steps. Errors in even one step have the potential to dramatically affect the functioning of the final product. Just one “killer defect” may cause device failure. The goal of the manufacturing process is to improve the overall yield of the process. For example, to obtain a 75% yield for a 50-step process (where a step may indicate the number of layers formed on a wafer), each individual step must have a yield greater than 99.4%. If an individual step has a yield of 95%, the overall process yield would be as low as 7-8%.

While high process yield is desirable in an IC chip manufacturing facility, maintaining a high substrate (i.e. wafer) throughput, defined as the number of substrates processed per hour, is also essential. High process yield and high substrate throughput may be impacted by the presence of a defect. This is especially if operator intervention is required for reviewing the defects. Thus, high throughput detection and identification of micro and nano-scale defects by inspection tools (such as a Scanning Electron Microscope (SEM)) is essential for maintaining high yield and low cost. Such an inspection tool may be an inspection system and may comprise an inspection apparatus.

A SEM comprises a scanning device and a detector apparatus. The scanning device and detector apparatus may be comprised in the inspection apparatus. The scanning device and the detector apparatus may be comprised in a common charged particle column or, as is disclosed herein, the scanning device and the detector apparatus may be comprised in a primary charged particle column and a secondary charged particle column respectively. The scanning device comprises an illumination apparatus that comprises an electron source, for generating primary electrons, and a projection apparatus for scanning a sample, such as a substrate, with one or more focused beams of primary electrons. The primary electrons interact with the sample and generate interaction products, such as secondary electrons and/or backscattered electrons. The detection apparatus captures the secondary electrons and/or backscattered electrons from the sample as the sample is scanned so that the SEM may create an image of the scanned area of the sample. For high throughput inspection, some of the inspection apparatuses use multiple focused beams, i.e. a multi-beam, of primary electrons. The component beams of the multi-beam may be referred to as sub-beams or beamlets. A multi-beam may scan different parts of a sample simultaneously. A multi-beam inspection apparatus may therefore inspect a sample at a much higher speed than a single-beam inspection apparatus.

In a multi-beam inspection apparatus, the paths of some of the primary electron beams are displaced away from the central axis, i.e. a mid-point of the primary electron-optical axis (also referred to herein as the charged particle axis), of the scanning device. To ensure all the electron beams arrive at the sample surface with substantially the same angle of incidence, sub-beam paths with a greater radial distance from the central axis need to be manipulated to move through a greater angle than the sub-beam paths with paths closer to the central axis. This stronger manipulation may cause aberrations that cause the resulting image to be blurry and out-of-focus. An example is spherical aberrations which bring the focus of each sub-beam path into a different focal plane. In particular, for sub-beam paths that are not on the central axis, the change in focal plane in the sub-beams is greater with the radial displacement from the central axis. Such aberrations and de-focus effects may remain associated with the secondary electrons from the target when they are detected, for example the shape and size of the spot formed by the sub-beam on the target will be affected. Such aberrations therefore degrade the quality of resulting images that are created during inspection.

An implementation of a known multi-beam inspection apparatus is described below.

The figures are schematic. Relative dimensions of components in drawings are therefore exaggerated for clarity. Within the following description of drawings the same or like reference numbers refer to the same or like components or entities, and only the differences with respect to the individual embodiments are described. While the description and drawings are directed to an electron-optical apparatus, it is appreciated that the embodiments are not used to limit the present disclosure to specific charged particles. References to electrons throughout the present document may therefore be more generally be considered to be references to charged particles, with the charged particles not necessarily being electrons.

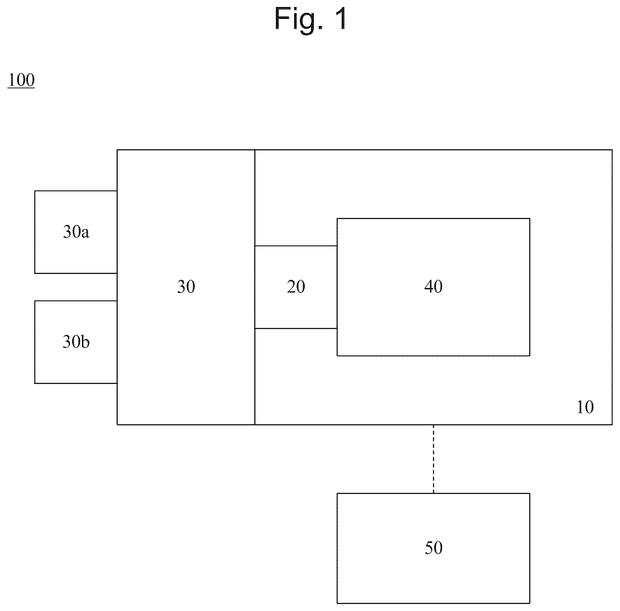

Reference is now made to FIG. 1, which is a schematic diagram illustrating an exemplary charged particle beam inspection apparatus 100. The charged particle beam inspection apparatus 100 of FIG. 1 includes a main chamber 10, a load lock chamber 20, an electron beam tool 40, an equipment front end module (EFEM) 30 and a controller 50.

EFEM 30 includes a first loading port 30a and a second loading port 30b. EFEM 30 may include additional loading port(s). First loading port 30a and second loading port 30b may, for example, receive substrate front opening unified pods (FOUPs) that contain substrates (e.g., semiconductor substrates or substrates made of other material(s)) or samples to be inspected (substrates, wafers and samples are collectively referred to as “samples” hereafter). One or more robot arms (not shown) in EFEM 30 transport the samples to load lock chamber 20.

Load lock chamber 20 is used to remove the gas around a sample. This creates a vacuum that is a local gas pressure lower than the pressure in the surrounding environment. The load lock chamber 20 may be connected to a load lock vacuum pump system (not shown), which removes gas particles in the load lock chamber 20. The operation of the load lock vacuum pump system enables the load lock chamber to reach a first pressure below the atmospheric pressure. After reaching the first pressure, one or more robot arms (not shown) transport the sample from load lock chamber 20 to main chamber 10. Main chamber 10 is connected to a main chamber vacuum pump system (not shown). The main chamber vacuum pump system removes gas molecules in main chamber 10 so that the pressure around the sample reaches a second pressure lower than the first pressure. After reaching the second pressure, the sample is transported to the electron beam tool by which it may be inspected. An electron beam tool 40 may comprise either a single beam or a multi-beam electron-optical apparatus.

Controller 50 is electronically connected to electron beam tool 40. Controller 50 may be a processor (such as a computer) configured to control the charged particle beam inspection apparatus 100. Controller 50 may also include a processing circuitry configured to execute various signal and image processing functions. While controller 50 is shown in FIG. 1 as being outside of the structure that includes main chamber 10, load lock chamber 20, and EFEM 30, it is appreciated that controller 50 may be part of the structure. The controller 50 may be located in one of the component elements of the charged particle beam inspection apparatus or it may be distributed over at least two of the component elements. While the present disclosure provides examples of main chamber 10 housing an electron beam inspection tool, it should be noted that aspects of the disclosure in their broadest sense are not limited to a chamber housing an electron beam inspection tool. Rather, it is appreciated that the foregoing principles may also be applied to other tools and other arrangements of apparatus, that operate under the second pressure.

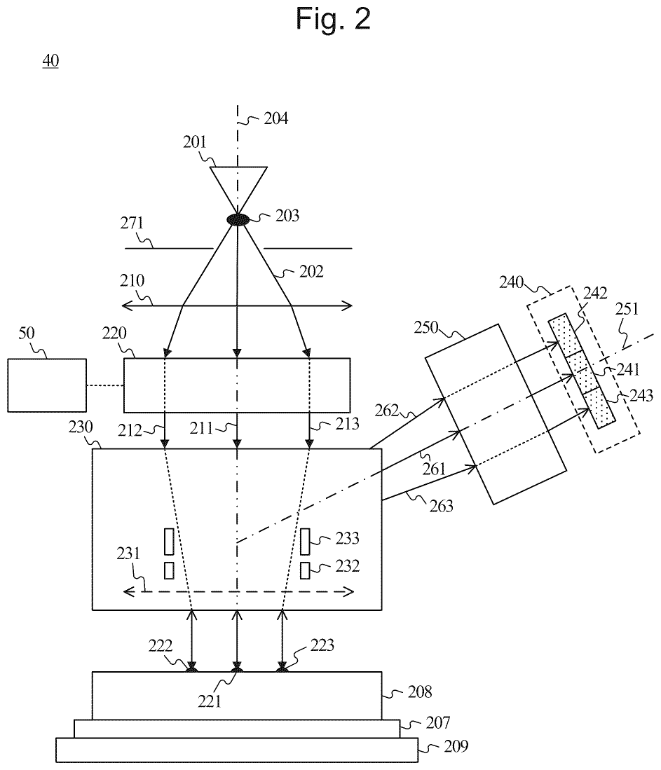

Reference is now made to FIG. 2, which is a schematic diagram illustrating an exemplary electron beam tool 40 including a multi-beam inspection tool that is part of the exemplary charged particle beam inspection apparatus 100 of FIG. 1. Multi-beam electron beam tool 40 (also referred to herein as apparatus 40) comprises an electron source 201, a gun aperture plate 271, a condenser lens 210, a source conversion unit 220, a primary projection apparatus 230, a motorized stage 209, and a sample holder 207. The electron source 201, a gun aperture plate 271, a condenser lens 210, a source conversion unit 220 are the components of an illumination apparatus comprised by the multi-beam electron beam tool 40. The sample holder 207 is supported by motorized stage 209 so as to hold a sample 208 (e.g., a substrate or a mask) for inspection. Multi-beam electron beam tool 40 may further comprise a secondary projection apparatus 250 and an associated electron detection device 240. The secondary projection apparatus 250 may be referred to as the secondary column. Primary projection apparatus 230 may comprise an objective lens 231. Electron detection device 240 may comprise a plurality of detection elements 241, 242, and 243. A beam separator 233 and a deflection scanning unit 232 may be positioned inside primary projection apparatus 230.

The components that are used to generate a primary beam may be aligned with a primary electron-optical axis of the apparatus 40. These components may include: the electron source 201, gun aperture plate 271, condenser lens 210, source conversion unit 220, beam separator 233, deflection scanning unit 232, and primary projection apparatus 230. Secondary projection apparatus 250 and its associated electron detection device 240 may be aligned with a secondary electron-optical axis 251 of apparatus 40.

The primary electron-optical axis 204 is comprised by the electron-optical axis of the of the part of electron beam tool 40 that is the illumination apparatus. The secondary electron-optical axis 251 is the electron-optical axis of the of the part of electron beam tool 40 that is a detection apparatus. The primary electron-optical axis 204 may also be referred to herein as the primary optical axis (to aid case of reference) or charged particle optical axis. The secondary electron-optical axis 251 may also be referred to herein as the secondary optical axis or the secondary charged particle optical axis.

Electron source 201 may comprise a cathode (not shown) and an extractor or anode (not shown). During operation, electron source 201 is configured to emit electrons as primary electrons from the cathode. The primary electrons are extracted or accelerated by the extractor and/or the anode to form a primary electron beam 202 that forms a primary beam crossover (virtual or real) 203. Primary electron beam 202 may be visualized as being emitted from primary beam crossover 203.

The formed primary electron beam 202 may be a single beam and a multi-beam may be generated from the single beam. At different locations along the beam path, the primary electron beam 202 may therefore be either a single beam or a multi-beam. By the time it reaches the sample, and preferably before it reaches the projection apparatus, the primary electron beam 202 is a multi-beam. Such a multi-beam may be generated from the primary electron beam in a number of different ways. For example, the multi-beam may be generated by a multi-beam array located before the crossover 203, a multi-beam array located in the source conversion unit 220, or a multi-beam array located at any point in between these locations. A multi-beam array may comprise a plurality of electron beam manipulating elements arranged in an array across the beam path. Each manipulating element may influence at least part of the primary electron beam to generate a sub-beam. Thus the multi-beam array interacts with an incident primary beam path to generate a multi-beam path down-beam of the multi-beam array. The interaction of the multi-beam array with the primary beam may include one or more aperture arrays, individual deflectors e.g. per sub-beam, lenses, stigmators and (aberration) correctors, again e.g. per sub-beam.

Gun aperture plate 271, in operation, is configured to block off peripheral electrons of primary electron beam 202 to reduce Coulomb effect. The Coulomb effect may enlarge the size of each of probe spots 221, 222, and 223 of primary sub-beams 211, 212, 213, and therefore deteriorate inspection resolution. A gun aperture plate 271 may also include multiple openings for generating primary sub-beams (not shown) even before the source conversion unit 220 and may be referred to as a coulomb aperture array.

Condenser lens 210 is configured to focus (or collimate) primary electron beam 202. In some embodiments, the condenser lens 210 may be designed to focus (or collimate) primary electron beam 202 to become a substantially parallel beam and be substantially normally incident onto source conversion unit 220. Condenser lens 210 may be a movable condenser lens that may be configured so that the position of its principle plane is movable. In some embodiments, the movable condenser lens may be configured to physically move, e.g. along the optical axis 204 (which may correspond to the central axis). Alternatively, the movable condenser lens may be constituted of two or more electro-optical elements (lenses) in which the principle plane of the condenser lens moves with a variation of the strength of the individual electro-optical elements. The (movable) condenser lens may be configured to be magnetic, electrostatic or a combination of magnetic and electrostatic lenses. In some embodiments, the condenser lens 210 may be an anti-rotation condenser lens. The anti-rotation condenser lens may be configured to keep the rotation angles unchanged when the focusing power (collimating power) of condenser lens 210 is changed and/or when the principle plane of the condenser lens moves.

In some embodiments of the source conversion unit 220, the source conversion unit 220 may comprise an image-forming element array, an aberration compensator array, a beam-limit aperture array, and a pre-bending micro-deflector array. The pre-bending micro-deflector array may, for example, be optional and may be present in some embodiments in which the condenser lens does not ensure substantially normal incidence of sub-beams originating from the coulomb aperture array onto e.g. the beam-limit aperture array, the image-forming element array, and/or the aberration compensator array. The image-forming element array may be configured to generate the plurality of sub-beams in the multi-beam path, i.e. primary sub-beams 211, 212, 213 which each may have a respective path or sub-beam path. The image forming element array may, for example, comprise a plurality electron beam manipulators such as micro-deflectors or micro-lenses (or a combination of both) to influence the plurality of primary sub-beams 211, 212, 213 of primary electron beam 202 and to form a plurality of parallel images (virtual or real) of primary beam crossover 203, one for each of the primary sub-beams 211, 212, and 213. The aberration compensator array may, for example, comprise a field curvature compensator array (not shown) and an astigmatism compensator array (not shown). The field curvature compensator array may, for example, comprise a plurality of micro-lenses to compensate field curvature aberrations of the primary sub-beams 211, 212, and 213. The astigmatism compensator array may comprise a plurality of micro-stigmators to compensate astigmatism aberrations of the primary sub-beams 211, 212, and 213. The beam-limit aperture array may be configured to define the diameters of individual primary sub-beams 211, 212, and 213. FIG. 2 shows three primary sub-beams 211, 212, and 213 as an example, and it should be understood that source conversion unit 220 may be configured to form any number of primary sub-beams. Controller 50 may be connected to various parts of charged particle beam inspection apparatus 100 of FIG. 1, such as source conversion unit 220, electron detection device 240, primary projection apparatus 230, or motorized stage 209. As explained in further detail below, controller 50 may perform various image and signal processing functions. Controller 50 may also generate various control signals to govern operations of the charged particle beam inspection apparatus, including the charged particle multi-beam apparatus.

Condenser lens 210 may further be configured to adjust electric currents of primary sub-beams 211, 212, 213 down-beam of source conversion unit 220 by varying the focusing power (collimating power) of condenser lens 210. Alternatively, or additionally, the electric currents of the primary sub-beams 211, 212, 213 may be changed by altering the radial sizes of beam-limit apertures within the beam-limit aperture array corresponding to the individual primary sub-beams 211, 212, 213. The radial dimension may be with respect to the path of the sub-beam through the aperture or an axis which may be parallel with central axis. The path of the sub-beam and the axis may correspond with each other.

Objective lens 231 may be configured to focus sub-beams 211, 212, and 213 onto the sample 208 for inspection and, in the current example, may form three probe spots 221, 222, and 223 on the surface of sample 208.

Beam separator 233 may be, for example, a Wien filter comprising an electrostatic dipole field and a magnetic dipole field (not shown in FIG. 2). In operation, beam separator 233 may be configured to exert an electrostatic force by electrostatic dipole field on individual electrons of primary sub-beams 211, 212, and 213. In some embodiments, the electrostatic force is equal in magnitude but opposite in direction to the magnetic force exerted by magnetic dipole field of beam separator 233 on the individual primary electrons of the primary sub-beams 211, 212, and 213.

Primary sub-beams 211, 212, and 213 may therefore pass at least substantially straight through beam separator 233 with at least substantially zero deflection angles. The direction of the magnetic force depends on the direction of motion of the electrons while the direction of the electrostatic force does not depend on the direction of motion of the electrons. So because the secondary electrons and backscattered electrons generally move in an opposite direction compared to the primary electrons, the magnetic force exerted on the secondary electrons and backscattered electrons will no longer cancel the electrostatic force and as a result the secondary electrons and backscattered electrons moving through the beam separator 233 will be deflected away from the optical axis 204.

Deflection scanning unit 232, in operation, is configured to deflect primary sub-beams 211, 212, and 213 to scan probe spots 221, 222, and 223 across individual scanning areas in a section of the surface of sample 208. In response to incidence of primary sub-beams 211, 212, and 213 or probe spots 221, 222, and 223 on sample 208, electrons are generated from the sample 208 which include secondary electrons and backscattered electrons. In the current example, the secondary electrons propagate in three secondary electron beams 261, 262, and 263. The secondary electron beams 261, 262, and 263 typically have secondary electrons (having electron energy≤50 eV) and may also have at least some of the backscattered electrons (having electron energy between 50 eV and the landing energy of primary sub-beams 211, 212, and 213). The beam separator 233 is arranged to deflect the path of the secondary electron beams 261, 262, and 263 towards the secondary projection apparatus 250. The secondary projection apparatus 250 subsequently focuses the path of secondary electron beams 261, 262, and 263 onto a plurality of detection regions 241, 242, and 243 of electron detection device 240. The detection regions may, for example, be the separate detection elements 241, 242, and 243 that are arranged to detect corresponding secondary electron beams 261, 262, and 263. The detection regions may generate corresponding signals which are, for example, sent to controller 50 or a signal processing system (not shown), e.g. to construct images of the corresponding scanned areas of sample 208.

The detection elements 241, 242, and 243 may detect the corresponding secondary electron beams 261, 262, and 263. On incidence of secondary electron beams with the detection elements 241, 242 and 243, the elements may generate corresponding intensity signal outputs (not shown). The outputs may be directed to an image processing system (e.g., controller 50). Each detection element 241, 242, and 243 may comprise one or more pixels. The intensity signal output of a detection element may be a sum of signals generated by all the pixels within the detection element.

The controller 50 may comprise image processing system that includes an image acquirer (not shown) and a storage device (not shown). For example, the controller may comprise a processor, computer, server, mainframe host, terminals, personal computer, any kind of mobile computing devices, and the like, or a combination thereof. The image acquirer may comprise at least part of the processing function of the controller. Thus the image acquirer may comprise at least one or more processors. The image acquirer may be communicatively coupled to an electron detection device 240 of the apparatus 40 permitting signal communication, such as an electrical conductor, optical fiber cable, portable storage media, IR, Bluetooth, internet, wireless network, wireless radio, among others, or a combination thereof. The image acquirer may receive a signal from electron detection device 240, may process the data comprised in the signal and may construct an image therefrom. The image acquirer may thus acquire images of sample 208. The image acquirer may also perform various post-processing functions, such as generating contours, superimposing indicators on an acquired image, and the like. The image acquirer may be configured to perform adjustments of brightness and contrast, etc. of acquired images. The storage may be a storage medium such as a hard disk, flash drive, cloud storage, random access memory (RAM), other types of computer readable memory, and the like. The storage may be coupled to the image acquirer and may be used for saving scanned raw image data as original images, and post-processed images.

The image acquirer may acquire one or more images of a sample based on an imaging signal received from the electron detection device 240. An imaging signal may correspond to a scanning operation for conducting charged particle imaging. An acquired image may be a single image comprising a plurality of imaging areas. The single image may be stored in the storage. The single image may be an original image that may be divided into a plurality of regions. Each of the regions may comprise one imaging area containing a feature of sample 208. The acquired images may comprise multiple images of a single imaging area of sample 208 sampled multiple times over a time period. The multiple images may be stored in the storage. The controller 50 may be configured to perform image processing steps with the multiple images of the same location of sample 208.

The controller 50 may include measurement circuitry (e.g., analog-to-digital converters) to obtain a distribution of the detected secondary electrons. The electron distribution data, collected during a detection time window, may be used in combination with corresponding scan path data of each of primary sub-beams 211, 212, and 213 incident on the sample surface, to reconstruct images of the sample structures under inspection. The reconstructed images may be used to reveal various features of the internal or external structures of sample 208. The reconstructed images m thereby be used to reveal any defects that may exist in the sample.

The controller 50 may, e.g. further control the motorized stage 209 to move the sample 208 during, before or after inspection of the sample 208. In some embodiments, the controller 50 may enable the motorized stage 209 to move sample 208 in a direction, e.g. continuously, for example at a constant speed, at least during sample inspection. The controller 50 may control movement of the motorized stage 209 so that the speed of the movement of the sample 208 changes, e.g. dependent on various parameters. For example, the controller may control the stage speed (including its direction) depending on the characteristics of the inspection steps of scanning process.

Although FIG. 2 shows that apparatus 40 uses three primary electron sub-beams, it is appreciated that apparatus 40 may use two or more number of primary electron sub-beams. The present disclosure does not limit the number of primary electron beams used in apparatus 40.

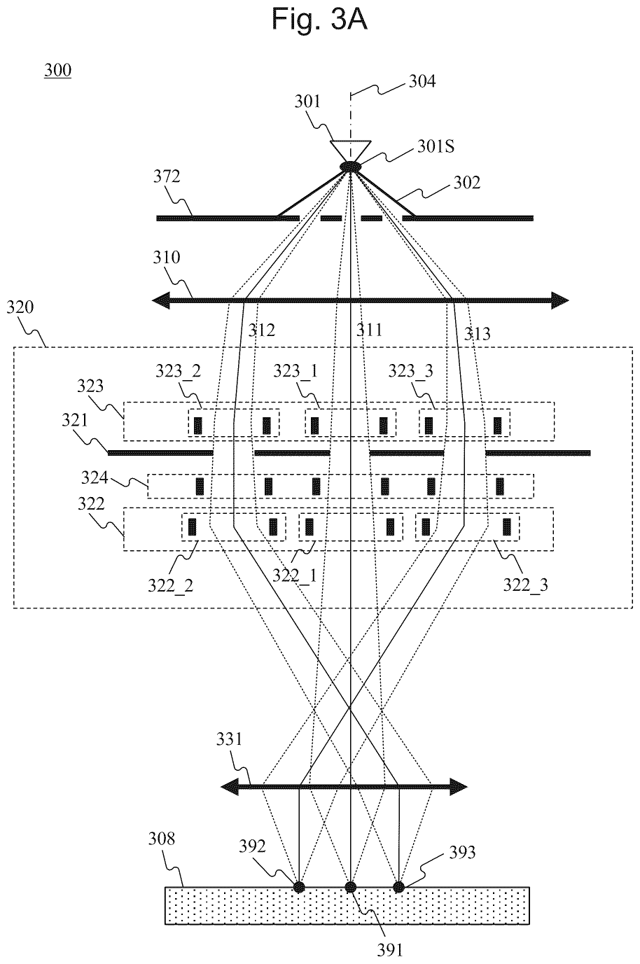

Reference is now made to FIG. 3A, which is a schematic diagram of exemplary multi-beam apparatus illustrating an exemplary configuration of source conversion unit of the exemplary charged particle beam inspection apparatus of FIG. 1. The apparatus 300 may comprise an election source 301, a pre-sub-beam-forming aperture array 372 (further also referred to as coulomb aperture array 372), a condenser lens 310 (similar to condenser lens 210 of FIG. 2), a source conversion unit 320, an objective lens 331 (similar to objective lens 231 of FIG. 2), and a sample 308 (similar to sample 208 of FIG. 2). The election source 301, the coulomb aperture array 372, the condenser lens 310 may be the components of an illumination apparatus comprised by the apparatus 300. The source conversion unit 320 and objective lens 331 may be the components of a projection apparatus comprised by the apparatus 300. The source conversion unit 320 may be similar to source conversion unit 220 of FIG. 2 in which the image-forming element array of FIG. 2 is image-forming element array 322, the aberration compensator array of FIG. 2 is aberration compensator array 324, the beam-limit aperture array of FIG. 2 is beam-limit aperture array 321, and the pre-bending micro-deflector array of FIG. 2 is pre-bending micro-deflector array 323. The election source 301, the coulomb aperture array 372, the condenser lens 310, the source conversion unit 320, and the objective lens 331 are aligned with a primary electron-optical axis 304 of the apparatus. The electron source 301 generates a primary-electron beam 302 generally along the primary electron-optical axis 304 and with a source crossover (virtual or real) 301S. The coulomb aperture array 372 cuts the peripheral electrons of primary electron beam 302 to reduce a consequential Coulomb effect. The primary-electron beam 302 may be trimmed into a specified number of sub-beams, such as three sub-beams 311, 312 and 313, by the coulomb aperture array 372 of a pre-sub-beam-forming mechanism. Although three sub-beams and their paths are referred to in the previous and following description, it should be understood that the description is intended to apply an apparatus, tool, or system with any number of sub-beams.

The source conversion unit 320 may include a beamlet-limit aperture array 321 with beam-limit apertures configured to define the outer dimensions of the sub-beams 311, 312, and 313 of the primary electron beam 302. The source conversion unit 320 may also include an image-forming element array 322 with image-forming micro-deflectors, 322_1, 322_2, and 322_3. There is a respective micro-deflector associated with the path of each sub-beam. The micro-deflectors 322_1, 322_2, and 322_3 are configured to deflect the paths of the sub-beams 311, 312, and 313 towards the electron-optical axis 304. The deflected sub-beams 311, 312 and 313 form virtual images (not shown) of source crossover 301S. In the current example, these virtual images are projected onto the sample 308 by the objective lens 331 and form probe spots thereon, which are the three probe spots, 391, 392, and 393. Each probe spot corresponds to the location of incidence of a sub-beam path on the sample surface. The source conversion unit 320 may further comprise an aberration compensator array 324 configured to compensate aberrations that may be present in each of the sub-beams. The aberration compensator array 324 may, for example, include a field curvature compensator array (not shown) with micro-lenses. The field curvature compensator and micro-lenses may, for example, be configured to compensate the individual sub-beams for field curvature aberrations evident in the probe spots, 391, 392, and 393. The aberration compensator array 324 may include an astigmatism compensator array (not shown) with micro-stigmators. The micro-stigmators may, for example, be controlled to operate on the sub-beams to compensate astigmatism aberrations that are otherwise present in the probe spots, 391, 392, and 393.

The source conversion unit 320 may further comprise a pre-bending micro-deflector array 323 with pre-bending micro-deflectors 323_1, 323_2, and 323_3 to bend the sub-beams 311, 312, and 313 respectively. The pre-bending micro-deflectors 323_1, 323_2, and 323_3 may bend the path of the sub-beams onto the beamlet-limit aperture array 321. In some embodiments, the pre-bending micro-deflector array 323 may be configured to bend the sub-beam path of sub-beams towards the orthogonal of the plane of on beamlet-limit aperture array 321. In some embodiments, the condenser lens 310 may adjust the path direction of the sub-beams onto the beamlet-limit aperture array 321. The condenser lens 310 may, for example, focus (collimate) the three sub-beams 311, 312, and 313 to become substantially parallel beams along primary electron-optical axis 304, so that the three sub-beams 311, 312, and 313 incident substantially perpendicularly onto source conversion unit 320, which may correspond to the beamlet-limit aperture array 321. In some embodiments, the pre-bending micro-deflector array 323 may not be necessary.

The image-forming element array 322, the aberration compensator array 324, and the pre-bending micro-deflector array 323 may comprise multiple layers of sub-beam manipulating devices, some of which may be in the form or arrays, for example: micro-deflectors, micro-lenses, or micro-stigmators.

In the current example of the source conversion unit 320, the sub-beams 311, 312 and 313 of the primary electron beam 302 are respectively deflected by the micro-deflectors 322_1, 322_2 and 322_3 of image-forming element array 322 towards the primary electron-optical axis 304. It should be understood that the sub-beam 311 path may already correspond to the electron-optical axis 304 prior to reaching micro-deflector 322_1, accordingly the sub-beam 311 path may not be deflected by micro-deflector 322_1.

The objective lens 331 focuses the sub-beams onto the surface of the sample 308, i.e., it projects the three virtual images onto the sample surface. The three images formed by three sub-beams 311 to 313 on the sample surface form three probe spots 391, 392 and 393 thereon. In some embodiments the deflection angles of sub-beams 311 to 313 are adjusted to pass through or approach the front focal point of objective lens 331 to reduce or limit the off-axis aberrations of three probe spots 391 to 393.

In the example of a multi-beam inspection tool 300 as shown in FIG. 3A the beam path of the secondary electrons, beam separator (similar as Wien filter 233), secondary projection optics (similar as secondary projection optics 250 of FIG. 2) and electron detection device (similar as electron detection device 240) have been omitted for clarity reasons. Is should be clear however that similar beam separator, secondary projection optics and electron detection device may be present in the current example of FIG. 3A to register and generate an image of the sample surface using the secondary electrons or backscattered electrons.

At least some of the above-described components in FIG. 2 and FIG. 3A may individually, or in combination with each other, be referred to as a manipulator array, or manipulator, because they manipulate one or more beams, or sub-beams, of charged particles.

The above-described embodiments of multi-beam inspection tools comprise a multi-beam charged particle apparatus, that may be referred to as a multi-beam charged particle optical apparatus, with a single source of charged particles. The multi-beam charged particle apparatus comprises an illumination apparatus and a projection apparatus. The illumination apparatus may generate a multi-beam of charged particles from the beam of electrons from the source. The projection apparatus projects a multi-beam of charged particles towards a sample. At least part of the surface of a sample may be scanned with the multi-beam of charged particles.

A multi-beam charged particle apparatus comprises one or more electron-optical devices for manipulating the sub-beams of the multi-beam of charged particles. The one or more electron-optical devices may be comprised in a charged particle column such as the primary charged particle column. The one or more electron-optical devices may be comprised in the scanning device The applied manipulation may be, for example, a deflection of the paths of sub-beams and/or a focusing operation applied to the sub-beams for example along the paths of the sub-beams towards a sample. The one or more electron-optical devices may comprise MEMS, or at least may be manufactured using MEMS fabrication techniques.

The charged particle apparatus may comprise beam path manipulators, such as macro beam path manipulators, located up-beam of the electron-optical device and, optionally, in the electron-optical device. Beam paths may be manipulated linearly in directions orthogonal to the charged particle axis, i.e. optical axis; that is the beam path manipulators may be deflectors such as macro-deflectors. In such a single beam system, the path of the charged particle beam may correspond to the central axis. For example, two electrostatic deflector sets operating across the whole beam. The two electrostatic deflector sets may be configured to deflect the beam path in orthogonal directions. Each electrostatic deflector set may comprise two electrostatic deflectors located sequentially along the beam path. The first electrostatic deflector of each set applies a correcting deflection and the second electrostatic deflector restores the beam to the correct angle of incidence on the electron-optical device. The correcting deflection applied by the first electrostatic deflector may be an over correction so that the second electrostatic deflector can apply a deflection for ensuring the desired angle of incidence to the MEMS. The location of the electrostatic deflector sets could be at a number of locations up-beam of the electron-optical device. Beam paths may be manipulated rotationally. Rotational corrections may be applied by a magnetic lens. Rotational corrections may additionally, or alternatively, be achieved by an existing magnetic lens such as the condenser lens arrangement.

Embodiments also include a charged particle projection apparatus that divides a charged particle beam from a source into a plurality of sub-beams. A plurality of respective objective lenses may project the sub-beams onto a sample. In some embodiments, a plurality of condenser lenses is provided up-beam from the objective lenses. The condenser lenses focus each of the sub-beams to an intermediate focus up-beam of the objective lenses. In some embodiments, collimators are provided up-beam from the objective lenses. Correctors may be provided to reduce focus error and/or aberrations. In some embodiments, such correctors are integrated into or positioned directly adjacent to the objective lenses. Where condenser lenses are provided, such correctors may additionally, or alternatively, be integrated into, or positioned directly adjacent to, the condenser lenses and/or positioned in, or directly adjacent to, the intermediate foci. A detector is provided to detect charged particles emitted by the sample. The detector may be integrated into the objective lens. The detector may be on the bottom surface of the objective lens so as to face a sample in use. The electron-optical devices, such as condenser lenses, objective lenses and/or detector may be formed as MEMS and/or CMOS devices. A CMOS device may comprise circuitry integrated into the structure of the electron optical device. For example an electron optical device may comprise a substrate with layers of circuitry for operating an array of electron-optical elements in and/or on the substrate. The array of electron-optical elements may be an array of manipulators as herein disclosed. See for example US2012/0305798 filed 30 May 2012 and WO2012/148267 which are herein incorporated by reference so far as arrays of manipulators and their related wiring or integrated circuitry.

In such a multi-beam arrangement, the paths of the sub-beams may be parallel with the central axis. The sub-beams may have such a common orientation when the multi-beam is collimated. The sub-beams may diverge or converge. In such arrangement with divergent or convergent sub-beams, most of the sub-beams are not parallel with the optical axis. At least the path of the most centrally positioned beam of the multi-beam may be parallel with the central axis.

As an example of an array, a 3×3 micro-deflector array configuration that can deflect a total of nine beamlets simultaneously is illustrated in FIG. 3B. FIG. 3B illustrates that each of image-forming micro-deflectors 322_1, 322_2, or 322_3 may comprise 4 electrodes. As the number of beamlets increases, the size of the array may increase as well. Note although an array of nine deflector assemblies (generally manipulators) is shown, arrays can exist from this arrangement to five by five, seven by seven, eleven by eleven to as many as 5000 or more manipulators.

As shown above, a multi-beam projection tool such as SEM among other can include a great number of beam manipulators such as, but not limited to, micro-deflectors, micro-lenses, or micro-stigmators. As the physical sizes of IC components continue to shrink, accuracy of manipulating each of the beams in a multi-beam projection tool becomes more important. Even a small beam aberration caused by a micro beam manipulator can invoke a false defect detection from the finished IC, which can substantially degrade overall yield of the process. In SEM, multiple electron beams are aligned in the column (or scanning device) with a small pitch (e.g., 300 micrometer or less) and every beam is manipulated by electric fields generated by electrodes of beam manipulators. However, dielectric material in the vicinity of electron beam passages can be charged and cause distortions of electric fields formed in the passages. Such electric field distortion can lead to degradation of electron-optical properties of beam manipulators. That is, electric field distortion can cause beam aberrations. To avoid such electric field distortion in beam manipulators, forming a uniform electric field in the beam passages of beam manipulators during operation can help alleviate these issues. This can be achieved by implementing uniform charge distribution on beam passage forming surfaces of beam manipulators.

Although beam manipulators are described with respect to a charged particle beam inspection system (e.g., SEM), the disclosure is not so limited. The present disclosure can be applied to beam manipulators utilized in other types of electron optical systems such as illumination systems, projection systems, e-beam lithography tools, e-beam inspection systems, etc. These electron-optical systems comprise a charged particle column comprising an electron-optical component such as a manipulator. The manipulator may be: a macro manipulator to operate on a single beam or all sub-beams; an array of meso manipulators in which each meso manipulator is configured to operate on a group of sub-beams; or a manipulator array such as depicted in FIG. 3B in which each beam has its own assigned manipulator. The manipulator array may be an array of electron-optical elements each being a manipulator for a sub-beam of the multi-beam, such as image-forming element array 322. It will be also appreciated that the present disclosure can be applied to embodiments in which multiple beam manipulators are aligned in an array, for example, illustrated in FIG. 3B, while the disclosure may be explained with respect to one beam manipulator.

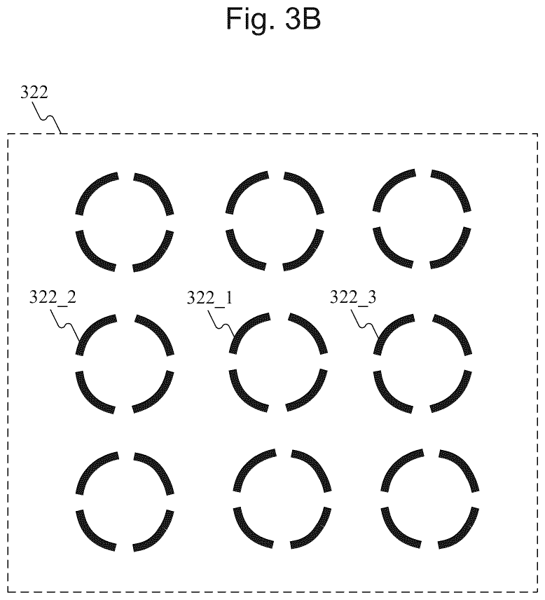

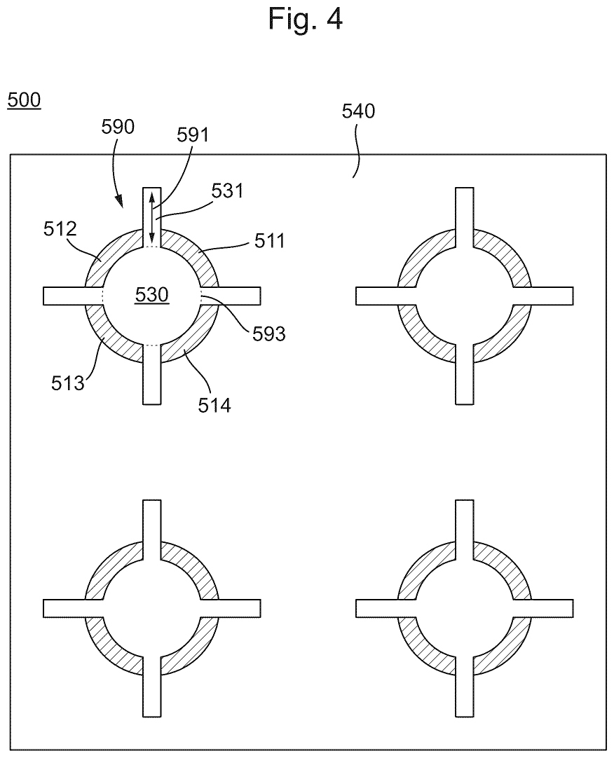

Reference is now made to FIG. 4 which is a schematic plan view of an exemplary beam manipulator array, consistent with embodiments of the present disclosure. It is noted such disclosure related to this example and all other embodiments of manipulator arrays may be applicable to a macro-manipulator and meso-manipulator so far as is possible.

Beam manipulator array 500 may influence various types of charged-particle beams, including but not limited to, a primary charged-particle beam, a secondary charged-particle beam, beamlets of the primary charged-particle beam, and beamlets of the secondary charged-particle beam.

The manipulator may be for manipulating a charged particle beam. The manipulator may be arranged in an array of manipulators (or a manipulator array). The manipulator array 500 may be for manipulating a plurality of charged particle beams in charged particle column which may comprise or be a projection system. The manipulator array may comprise a substrate 540. The substrate may be planar. The substrate 540 may have major surfaces. The major surfaces may oppose each other. A through-passage that defines associated apertures in the major surfaces. The apertures are the of the ends of the through-passage. The through passage is for passage of a path of a charged particle beam. A part of the surface of the through passage between the major surfaces is an inner wall. The inner wall of the through-passage between the major surfaces comprises or at least defines a plurality of electrodes. The electrodes configured to manipulate the charged particle beam.

Thus considering the manipulator 590 being in a manipulator array, defined in each of the major surfaces is a plurality of apertures. Each aperture 530 is for passage of a sub-beam of the multi-beam. The apertures may be arranged in an array in the substrate 540. Through passages connect respective apertures in each of the major surfaces. So there may be a plurality of through passages. The through passages are for passage of the paths of the plurality of sub-beams. Each through-passage has an interconnecting surface extending between the respective apertures in each of the major surfaces. Such a through passage is configured for passage of a respect beam of charged particles.

A beam manipulator array 500 may be formed in a body of an electrically non-conductive or semi-conductive substrate in various embodiments. In some embodiments, the substrate may be made of silicon, glass, germanium, sapphire, or any other suitable material consistent with the embodiments in this disclosure. The beam manipulator array 500 may be formed in the substrate by doping parts of the substrate. For example, the substrate 540 may be silicon and electrically conductive parts of the beam manipulator array may be made from doped silicon. Each electrode 511, 512, 513, 514 may comprise doped substrate. Thus electrode surfaces comprise doped substrate. That is the electrode surfaces are provided by a material of the substrate which is doped to adjust the conductivity of the substrate. For the substrate material used to provide the electrode surfaces the doping improves the conductivity of the material. Furthermore electrostatic properties are determined with respect to charge and area. Therefore the references to a surface, and thus the effective area of the surface, is reference to the electrostatic properties and thus function of the surface. It is intended that, in referring to a surface, the material that provides the surface has sufficient thickness to enable the surface to provide those properties. For example the material of the substrate that is doped is doped to a sufficient depth to provide the desired surface properties.

The beam manipulator array 500 may include a substrate 540 and one or more beam manipulators, such as beam manipulator 590. While FIG. 4 shows an example of beam manipulator array with a two-by-two configuration i.e. with four manipulators, it is appreciated that the array may be any size. For example, arrays can exist from this arrangement to three by three, five by five, seven by seven, eleven by eleven, or two hundred manipulators to as many as 10000 or more manipulators.

In some embodiments, an electron aperture 530 may be formed through the substrate 540. The electron aperture 530 may be configured for passage of the charged particle beam to pass through. The electron aperture 530 may enclose the path of an electron beam and so preferably has a substantially circular shape at the surface (e.g. the upbeam surface) of the substrate 540 (e.g., as shown by a circular boundary 593). The electron aperture may be around a central beam axis which may correspond to the path of the electron beam. (It is noted that a path of a beam is the geometrical position of the beam relative to the aperture wen the manipulator is not in operation and thus beam the beam is not present). Where the electron-beam is uncollimated, the axis may correspond to a specific position or plane through the substrate which may be determined by convention such as one of the major surfaces of the substrate, such as an upbeam surface or a downbeam surface, or a midpoint between the major surfaces. The aperture 530 extends through the substrate 540 for example between the major surfaces of the substrate such as a through passage, and may be defined by electrodes 511, 512, 513, and 514. In some embodiments, the electrodes 511, 512, 513, and 514 may extend radially outward from the electron aperture 530. Here outward may be with respect to the path of the sub=beam through the aperture or an axis which is parallel to the central axis. The path of the sub-beam and the axis may correspond to each other. The electrodes may provide a part of a surface of the substrate 540, which may be referred to as an electrode planar surface. The electrode planar surfaces of the electrodes 511, 512, 513 and 514 are the part of the electrodes 511, 512, 513, and 514 shown in FIG. 4. The electrode planar surfaces of the electrodes 511, 512, 513 and 514 provide an effectively substantially circular shape. However, embodiments include the electron aperture 530 and the electrode planar surfaces of the electrodes 511, 512, 513 and 514 having any shape.

While the beam manipulator 590 is shown as having four electrodes 511, 512, 513, and 514 in FIG. 4, it is appreciated that a beam manipulator with four electrodes is an exemplary arrangement and the beam manipulator 590 may comprise any number of electrodes, including but not limited to six, eight, ten, twelve to as many as twenty four and more. The surface between adjoining electrodes (or adjacent electrodes) may be referred to as an electrically insulating region.

In various embodiments where the beam manipulator 590 includes a plurality of electrodes, such as four electrodes 511, 512, 513, and 514 as shown in FIG. 4, two adjacent electrodes among the plurality of electrodes may be interposed by, indeed spaced apart by a slot therebetween. The slot is defined by the radially extending side surfaces of two adjacent (and/or adjoining) electrodes. For example, the electrode 511 and the electrode 512 may be spaced apart by a slot 531. At least part of the slot may be referred to as a recess. The recess may be surface between adjoining electrodes. The recess may be referred to as a recessed surface. In some embodiments, the slot 531 may have a radial length longer than a radial length of the electrode 511 to ensure electrical isolation between two adjacent electrodes. For example, as shown in FIG. 4, a radial length of the slot 531 (shown as a radial distance 591) may be longer than a radial depth of the electrodes 511, 512, 513, and 514 which is shown as a radial distance 592 between the circular boundary 593 to the circular boundary 594. Thus FIG. 4 illustrates four slots (e.g. slot 531) between adjacent electrodes. However, there may be as many slots as desired. The number of slots may correspond to the number of electrodes comprised in the manipulator.

The through-passage further comprising recesses. The recesses extends away from the path of the charged particle beam or an axis (or central axis) of the through-passage. The recess is for isolating individual electrodes for example adjacent electrodes. Each recess defines a gap between the adjacent electrodes 511, 512, 513, 514. That is the surface (or doped surface) of adjacent electrodes may have a gap defined therebetween. The recess comprises an electrically insulating region between the adjacent electrodes (which may be referred to as separate adjacent electrodes). The surface of the through passage may be provided by an interconnecting surface that extends between the major surfaces, for example between the apertures of the through passage. Thus the interconnecting surface of each aperture defines the plurality of electrodes that extend between the respective apertures.

Each electrode 511, 512, 513, 514 is defined by a respective electrode surface. Thus the interconnecting surface of each aperture may define the plurality of recessed surfaces. Each recessed surface is between separate adjacent electrodes. Each recessed surface may extend outward from at least part of the adjacent electrodes 511, 512, 513, 514. Each recessed surface comprises outward electrode surfaces and the electrically insulating region. The outward electrode surface may extend radially outward for example with respect to the sub-beam path or an axis of a feature of the manipulator such as the through passage. Each outward electrode surfaces are of an electrode surface of each adjacent electrode. An electrically insulating region is configured to electrically insulate between the electrode surface of the adjacent electrodes 511, 512, 513, 514. The electrically insulating region may electrically insulate between the adjacent electrodes, desirably between adjoining (or adjacent) outward electrode surfaces The electrically insulating region thus extends between the major surfaces. The recessed surface is desirably recessed into the substrate deeper, desirably radially further, than the electrodes. That is the recessed surface may be extend further from the sub-beam path or the axis of the manipulator than the electrodes surfaces. Desirably the recessed surface is desirably recessed further into the substrate than at least one of the electrode surfaces of the adjacent electrodes.

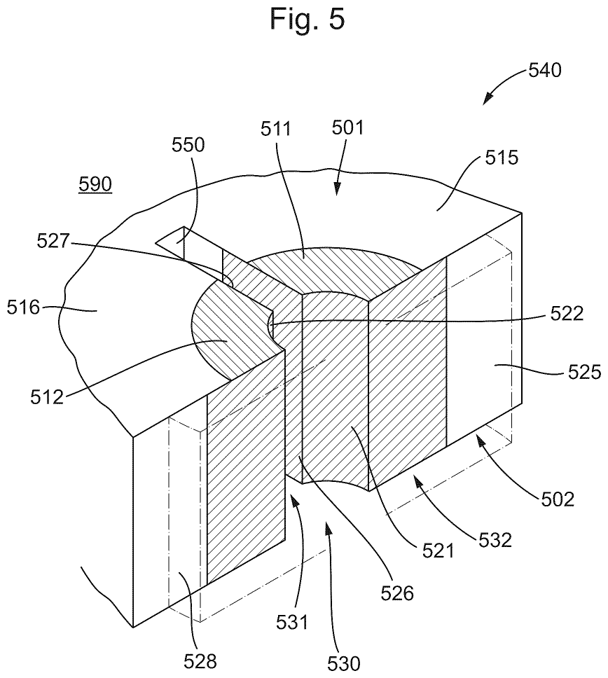

Reference is now made to FIG. 5 illustrating a schematic cross-sectional perspective view of beam manipulator 590 of beam manipulator array 500 of FIG. 4, consistent with embodiments of the present disclosure.

The substrate 540 may include two major surfaces, for example, an upper major surface 501 and a lower major surface 502. In some embodiments, the electron aperture 530 may extend through the two major surfaces 501, 502 of substrate 540. In some embodiments, the slot 531 may extend through the substrate 540 from the upper major surface 501 to the lower major surface 502. Thereby, the slot 531 can extend through the beam manipulator 590 through the thickness of the substrate. Resulting from one or more slots (such as slots 531 and 532) formed in the substrate 540, the substrate 540 may comprise one or more protruding portions (e.g., protruding portions 515 and 516). A protruding portion 515, 516 may protrude radially into the manipulator towards the electron aperture 530. There may be as many protruding portions as slots and electrodes.

Each of the protruding portions 515 and 516 may have two or more side surfaces facing slots adjacent to the corresponding protruding portion. For example, the protruding portion 515 may have side surfaces 525 and 526 that define surface of the portion, respectively, and each provide a radial surface of a slot. In some embodiments, the protruding portion 515 may further have an aperture facing surface 521, which meets the side surface 525 in one end and the side surface 526 in the other end. Similarly, the protruding portion 516 may have side surfaces 527 and 528, and an aperture facing surface 522. The aperture facing surfaces 521, 522 are radially inwardly facing surfaces. Together the aperture facing surfaces 521, 522 of the electrodes 511, 512, 513, 514 may be referred to as an inner wall. Such an aperture facing surface 521, 522 may be considered a part of the inner wall for example of the through-passage. Each aperture facing surface 521, 522 provides a part of an electrode surface of the corresponding electrode. The aperture facing surface 521, 522 may be referred to as an inward surface of the electrode surface. The radially inward facing surface may be curved for example around the intended path of a charged particle beam. Together all the aperture facing surfaces of the electrodes 511, 512, 513, 514, for example around the intended path of the charged particle beam, define the through passage. Thus at least a part of the surface of part of the through passage is arranged around a path of a beam of charged particles so as to face the path. In some embodiments, each of the protruding portions 515 and 516 may extend from the upper major surface 501 to the lower major surface 502 of the substrate 540. Adjoining or adjacent protruding portions 515, 516 may define a slot therebetween. For example, the side surface 527 of protruding portion 516, and the side surface 526 of the protruding portion 515 may face each other; form radial surfaces of the slot 531; and/or may be radially extending surfaces that define the side surfaces of the slot 531.

Some part of the protruding portions 515 and 516 form corresponding electrodes, 511 and 512, respectively. For example, as shown in FIG. 5, some surfaces of the protruding portion 515 close to the electron aperture 530 may be made of electrically conducting materials. The surfaces may include at least some part of the upper major surface 501, in an example extending radially outward from the aperture, the aperture facing surface 521, and the side surfaces 525, 526; thereby forming an electrode 511.

As shown in FIG. 5, the electrodes 511, 512 may extend between the upper major surface 501 and the lower major surface 502. The boundary surface between the electrodes 511, 512 and the rest of the substrate 540 may be substantially orthogonal to the planes of the upper major surface 501 and the lower major surface 502. That is to say, along the length of the electron aperture 530, the electrodes 511, 512 may have a substantially constant cross-section in planes parallel to the major surfaces 501, 502.

A distal end of slot 531 radially away from the electron aperture 530 may be a radial end surface 550. The radial end surface may extend through the substrate 540 from the upper major surface 501 to the lower major surface 502. The radial end surface may extend between the side surfaces 526, 527 of the adjoining protruding portion 515, 516. The radial end surface is positioned radially outward of the electrodes 511, 512 of the adjoining portions 515, 516.

The beam manipulator 590 may comprise a plurality of slots that have similar geometry between adjoining portions each having an electrode 511, 512, 513, 514. The side surfaces 526, 527 may take a topography having a geometry in plan view of any reasonable form. The side surfaces 526, 527 in plan view need not be planar and/or coplanar. One or both side surfaces in plan view may be curved or even sinusoidal (e.g. having a surface in a radially direction which is has different portions of having a curvature of opposing directions (e.g. the slot 531 may have a wavy form in plan view). The curved surfaces in plan view may define a curved slot therebetween. In plan view, the curved surfaces may be unidirectional in a slot, or it may be curved in more than one direction. The direction of curving may be clockwise, counter-clockwise; all in the same direction, or in different directions or alternate. Where the surfaces curve in more than one direction, the curves of the slot may be similar with distance from the aperture, different, or alternating in being similar and counter.

According to embodiments of the present disclosure, one or more charged particle beams or beamlets may be manipulated by electric fields generated by the beam manipulator 590. To generate electric fields to affect trajectories of one or more beams passing through the electron aperture 530, electrodes 511, 512, 513, and 514 may be routed, or wired, individually or collectively to a corresponding power source, which may be positioned outside of the charged particle column of for the example the SEM, or at least a vacuum chamber of the charged particle column. In some embodiments, electric circuits configured to provide a driving voltage or control signal to electrodes 511, 512, 513, and 514 may be formed in the substrate 540 and/or on an upper major surface of the substrate 540, such as the upper major surface 501. In arrangement the body of the substrate may function as an electrode and without routing.

The beam manipulator 590 including four electrodes such as in FIG. 4 may be configured in different ways to function differently. When all four electrodes are applied to one voltage potential, the beam manipulator 590 can function as a micro-lens. When the two pairs of opposite electrodes are applied to two voltages of the same substantially absolute value but opposite polarity, the beam manipulator 590 can function as a micro-stigmator. For example, in FIG. 4, when (i) one pair of electrodes facing each other among the four electrodes (such as 511 and 513) are applied to +V1, and (ii) the other pair of electrodes facing each other (such as 512 and 514) are applied to −V1, beam manipulator 590 functions as a micro-stigmator.

When (i) one pair of opposite electrodes (such as 511 and 513) are applied to a zero voltage, and (ii) the other pair of opposite electrodes (such as 512 and 514) are applied to two voltages of the same absolute value but opposite polarity, beam manipulator 590 can function as a micro-deflector. For example, in FIG. 4, when (i) electrodes 511 and 513 are applied to 0 V, and (ii) electrode 512 is applied to V2 and electrode 514 is applied to −V2, the beam manipulator 590 functions as a micro-deflector. A magnitude or polarity of a voltage applied to each of electrodes may be determined according to a target manipulation direction or manipulation degree of a beam passing through the electron aperture 530. In some embodiments, a controller (such as controller 50 of FIG. 2) may be configured to control voltage levels, voltage polarities, voltage application timing, etc. for each electrode included in beam manipulator 590.

In the present disclosure, a beam manipulator may be described as including a main body and an electrode. In beam manipulator 590 of FIG. 4, substrate 540 may form a main body of the beam manipulator 590 and electrodes 511, 512, 513, and 514 may be electrodes of beam manipulator 590. A main body may have a first surface, a second surface opposing the first surface, and an interconnecting surface extending between the first surface and the second surface. An aperture may be formed through the body according to embodiments of the present disclosure.

In some embodiments, substrate 540 may be etched to form electron aperture 530 extending through substrate 540 from the upper major surface 501 to the lower major surface 502. In some embodiments, substrate 540 may be etched to form slots extending through the substrate 540 from the upper major surface 501 to the lower major surface 502. The substrate 540 can be shaped for example using laser ablation, etching or any suitable fabrication technique. The electrodes may be formed by coating the formed substrate by using any suitable coating process. In some embodiments, the geometric shape of the slots may vary from the upper major surface 501 to the lower major surface 502 depending on the manufacturing process used. For example, the corners of the slots for example between each side surface 526, 527 and the radial end surface may become more curved with distance from the upper major surface 501.

Embodiments include techniques for manufacturing the beam manipulator 590 as shown in FIGS. 4 and 5, in addition to all other beam manipulators according to embodiments disclosed herein.

In particular, embodiments include manufacturing a beam manipulator by first forming both the insulating surfaces of the beam manipulator in a substrate and the openings through the substrate. The openings may include an aperture through the substrate, that is a through passage for charged particles (that may be an electron aperture), and the shapes of the slots between adjacent electrodes. The electrically conductive surfaces of the beam manipulator may then be made by doping some of the exposed surfaces of the substrate.

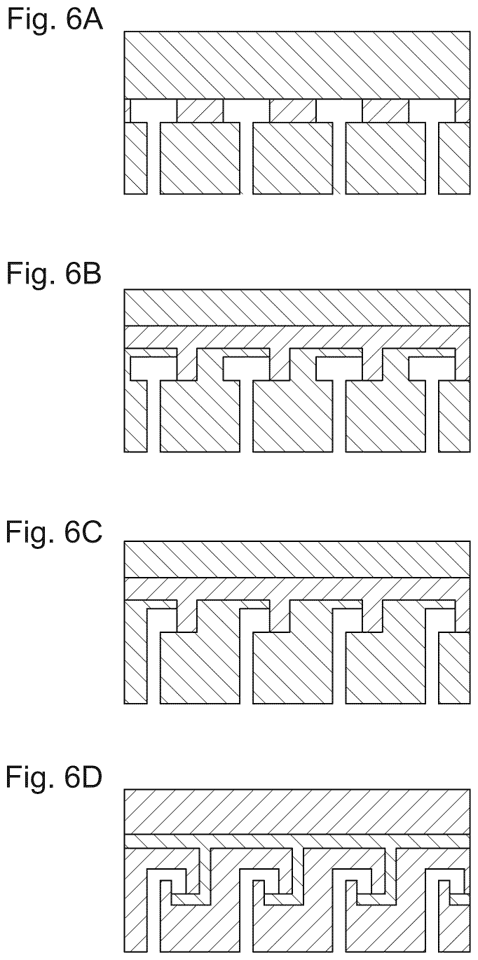

FIGS. 6A to 6D are schematic plan views of different arrangements of insulator formed in a substrate as well as openings formed within the substrate. In FIGS. 6A to 6D, the electrodes are shown in an exemplary linear arrangement, in plan, in order to demonstrate clearly the general shapes of the electrodes, slots and insulator patterns. However, in preferred implementations of beam manipulators according to embodiments, the electrodes are, in schematic plan view, instead arranged around a circular aperture, as shown in, and described with reference to, the beam manipulators in at least FIGS. 4 and 5. The arrangement of electrodes may therefore be located around an aperture, and/or multiples of the arrangement of electrodes may be located around an aperture. In a preferred implementation of some embodiments, the number of electrodes is a multiple of four. In FIGS. 6A to 6D, the insulator and slot may extend through the substrate between opposing major surfaces of the substrate, i.e. from an upper major surface to a lower major surface. The insulator may form an insulating ring. The insulator may be a mechanical support for the electrodes formed within the insulating ring. The insulating ring may be formed by patterning the ring into a major surface of the substrate and then etching the pattern to remove the ring. The etched part of the substrate may then be filled with dielectric. For example, the atomic layer deposition (ALD), chemical vapor deposition (CVD), and/or oxide growth processes may be performed to fill the etched part of the substrate with dielectric. The gaps/slots that define the shape of the electrodes may also be formed by patterning the substrate and then etching the pattern.

In FIGS. 6A and 6B, in schematic plan view, the openings provide the apertures in the major surfaces, and thereby an aperture in the substrate that is a through passage of charged particles through the substrate, as well as slots between adjacent electrodes. The slots shown and depicted in FIGS. 6A and 6B may be referred to as T shaped slots. A distal end of each slot radially away from the electron aperture may comprise a geometric shape in plan view. Each geometrical shape and thus slot may have the same design. One such geometrical shape is the depicted T shape. Such a slot may be defined by additional surfaces that may be considered to surround the slot. t. The T shape may comprise a stem and two bifurcated branches that meet at the distant end of the slot, s For example, the branch surfaces may define a first bifurcated branch of the two bifurcated es, in plan view. The other of the two bifurcated branches, a second bifurcated branch, is defined by branch surfaces that extend desirably in an opposing direction to the branch surfaces for the first bifurcated branch. The radial end surface of the slot may form a contiguous surface with a branch surface of one or both of the bifurcated branches. For example an end of the stem remote from the aperture intersects with a cross-piece which may be formed by the two bifurcated branches. A branch may be referred to as a tangential portion.

In some embodiments, the branch surfaces of the first and second branches may extend through the substrate, desirably between its two major surfaces. In some embodiments, the branched surfaces, and thus the branches may be positioned radially beyond electrode surface such as the electrode planar surfaces of each electrode. In some embodiments, the surface that define the bifurcated branches may define a space broader than the central stem portion of a T-shaped slot 531. In some embodiments, the at least one of the branch surfaces of one or both of the bifurcated branches may extend at least partly tangentially with respect to the electron aperture 530 or even the path of a charged particle beam through the aperture.

Accordingly, each T-shaped slot may include a center stem portion and two arm portions bifurcated from the center stem portion. Each slot may feature a recessed surface for example between adjoining electrodes. A portion of the recessed surface may define the stem. Different portions of the recessed surface may define the two arms.

This geometrical shape of slot, i.e. T shape slot, is known in single beam designs such as U.S. Pat. No. 5,245,194 filed Apr. 22, 1992, which is hereby incorporated by reference. However the fabrication techniques and electron-optical benefits has yet to be appreciated despite arrays of electron-optical manipulators being known in the art See for example US2012/0305798 filed 3 May 2011 which is hereby incorporated by reference at least with respect to the disclosed manipulator array.

As mentioned, such a T-shaped slot may have a stem portion and two arm portions bifurcated from the center stem portion. As depicted in in FIG. 6A the arm portions may be tangential portions at a distal end of a slot. However, the embodiments of the present disclosure may also relate to variations. For example the arm portions need not be located at the distal end of the slot. The arm portions may be spaced away from the distal portion, for example within a distal half of the slot. The arm portions need not be tangential, for example have a direction orthogonal to the direction in which the slot extends. For example an arm portion may be angled with respect to the slot. A slot need not have two arms but as many or as few arms as desired. For example a slot may have a single arm or angled portion. The arms portions of a slot with multiple arm portions may be angled differently with respect to the slot. For example a slot may have two arm portions of which one arm portion is tangential.

The openings in FIG. 6C differ from those in FIGS. 6A and 6B in that the slots between adjacent electrodes have, in plan view, have a different geometrical shape, which may be considered to be a substantial L-shape. That is to say, the slot is similar to a T-shaped slot but with the slot extending in only one of the bifurcations comprised by a T-shaped slot. The slot shown in FIG. 6C is an example of a slot with a single arm portion or angled portion. (An L shape may have a single branch extending from the stem of the slot, desirably at a distal end of the slot, desirably in a direction angled to the direction of the stem of the slot, e.g. an angled portion, desirable orthogonal to the direction of the stem of the slot, e.g. as a tangential portion. The single branch may be a single tangential portion).

In a variation of slot, at least one of the arm portions of the slot may have one or more secondary portion. A secondary portion of the slot is a branch off the arm portion (or thus a further or second ranked branch off the stem). The secondary portion may be positioned at any position along the arm portion. The secondary portion may be angled with respect to the direction of the arm, desirably orthogonal to the direction of the arm portion, which may have a tangential direction (e.g. as a tangential portion) with respect to the aperture 530. The secondary portion may have a direction (e.g. opposite) to the direction of the stem away from the aperture 530. The secondary portion may extend towards one of the two electrodes 511, 512 associated with the slot 531, desirably the closest electrode of the two electrodes 511, 512. The secondary portion may be angled towards a proximate electrode, desirably a most proximate electrode.

The openings in FIG. 6D differ from those in FIGS. 6A and 6B in that the slots between adjacent electrodes have a different geometrical shape, which may be considered to be substantial J-shape. A slot having a J-shape may be an example of a slot with a secondary portion (and an arm portion). (A J-shape of slot may be shaped (as an L shape) to have a single branch (or tangential portion) extending from the stem of the slot, desirably at a distal end of the slot, desirably in a direction angled desirable orthogonal to the direction of the stem of the slot, and a secondary portion or further branch. The secondary branch may extend at an angle from the branch desirably at a distal end of the branch and desirably in a direction substantially orthogonal to the branch optionally in a direction parallel to the stem).

In schematic plan view, the pattern that the insulator is arranged in electrically isolates conductive surfaces of adjacent electrodes from each other. With the pattern of the insulator shown in FIG. 6A, both of the radially extending surfaces at the distal ends of the two arm portions bifurcated from the center stem are insulators. With the pattern of the insulator shown in FIG. 6B, only one of the radially extending surfaces at the distal ends of the two arm portions bifurcated from the center stem is an insulator. With the pattern of the insulator shown in FIG. 6C, the radially extending surface of the L-shape slot, that is the furthest along the length of the slot from the aperture that is a through passage for charged particles, is an insulator. (An L shape slot may be shaped to have a single branch extending from the stem of the slot, desirably at a distal end of the slot). The slot of FIG. 6C has a tangential extension to the slot remote from the aperture or through passage. With the pattern of the insulator shown in FIG. 6D, the surface that is the furthest along the length of the J-shaped slot from the aperture that is a through passage for charged particles is an insulator. The slot of FIG. 6D is shaped as FIG. 6C with a tangential extension at the end of the slot remote from the aperture or through passage. Additionally the slot of FIG. 6D has at the end of the tangential extension, a radial inward extension. The slot of FIG. 6D therefore can be considered to take the appearance of a J′. Embodiments may also include other patterns of insulator for providing the insulator at other surfaces of each slot and/or with different shapes of slot.

After the insulator and openings have been formed in the substrate, a doping process may be performed to provide the conductive surfaces of the electrodes according to known manufacturing techniques. The substrate may be silicon, glass, germanium, sapphire, or any other suitable material consistent with the embodiments in this disclosure. The insulator may be silicon oxide or any other suitable material consistent with the embodiments in this disclosure. The conductive surfaces of the electrodes may be doped silicon. Thus electrode surfaces comprise doped substrate. Forming electrodes in this way beneficially enables more precisely define the electrode surfaces at least in the geometries of the present disclosure. Such geometries have multiple faces. Desirably having entire surface of the face of a geometry of a structure such as a slot such as depicted in FIGS. 6A to 6D may provide uniform and consistent surface properties of the respective faces. More consistent properties and function can be expected and may be provided by the electrodes around the sub-beam path and even between manipulators across the manipulator array. Electrode surfaces and the electrical isolation may be improved for example in terms of function and performance. Performance of the resulting manipulators may be ensured by having electrodes precisely defined or at least with greater precision than before, as provided herein. The recess may extend behind at least one of the adjacent electrodes relative to the path of the charged particle beam. A portion of the recess that extends behind at least one of the adjacent electrode may comprise at least part of the electrically insulating region. As described in embodiments disclosed herein, desirably all of the insulating region is behind at least one the adjacent electrodes.

Desirably the recess extends further radially outward from the path of the charged particle beam such as a sub-beam or the axis of a feature of the manipulator such as the through passage (which may be the same and herein after is referred to as the path) than the adjacent electrode. Desirably the recess extends radially further with respect to the path than at least one of the electrode surfaces of the adjacent electrodes. At least one of the electrode surfaces comprises a radially outward facing surface. The radially outward facing surface is comprised in the recess. Desirably the outward surface comprises the radially outward facing surface desirably with respect to the path of the charged particle beam for example a sub-beam. The adjacent electrodes may comprise outward electrode surface with respect to the path. The recess may comprise a distal inward electrode surface of at least one of the adjacent electrodes. The distance inward electrode surface may be of at least one of the electrode surfaces of the adjacent electrodes. The distal inward electrode surface may be radially outward of the inner wall with respect to the path. The at least one of the electrodes comprise a distal inward electrode surface that is radially outward of the inner wall with respect to the path.

At least one of the electrode surfaces comprises a radially inwardly facing surface. Desirably the at least one of the electrodes comprises an inward surface with respect to the path. Desirably the at least one of the electrode surfaces comprise an inward surface with respect to the path. At least one of the radially inwardly facing surfaces comprising a curved surface. Desirably the radially inwardly facing surfaces of the electrodes substantially define the inner wall. At least a part of the surface of part of the through passage is arranged around a path of a beam of charged particles so as to face the path. Desirably the electrically insulating region is configured to electrically insulate between the separate adjacent electrodes. Desirably the electrically insulating region is between adjoining outward electrode surfaces.

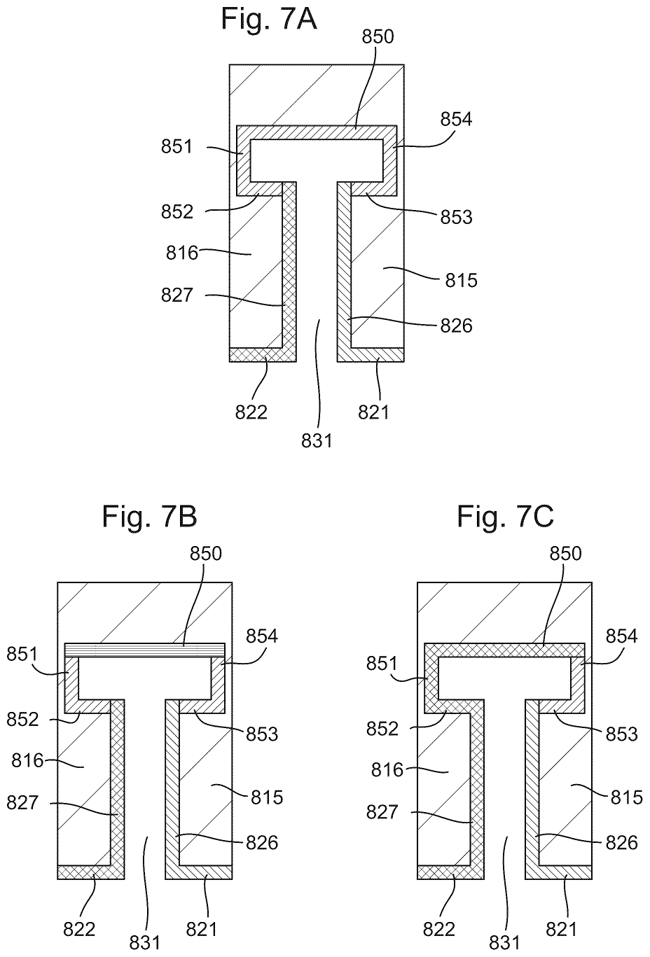

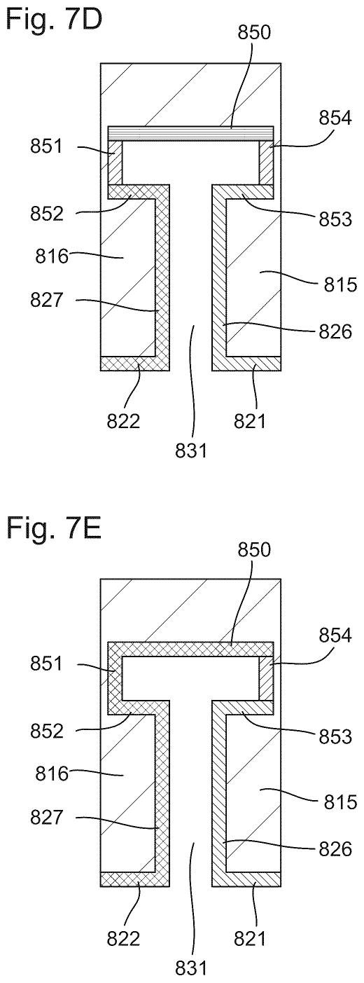

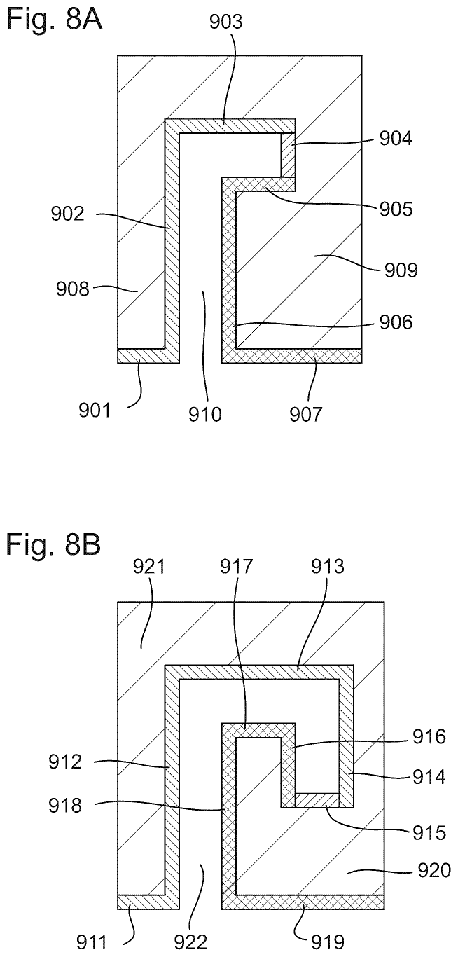

FIGS. 7A to 7E, and FIGS. 8A and 8B, each show a slot arrangement between adjacent electrodes of beam manipulators according to embodiments. Although a single slot between adjacent electrodes is shown, it should be understood that a complete beam manipulator according to embodiments may comprise a plurality of electrodes, with all of the electrodes having the same shape, and a plurality of slots, with all of the slots having the same shape and each slot being between a pair of adjacent electrodes. The number of electrodes may be two or more, such as four or eight. In schematic plan view, the plurality of electrodes and slots may be arranged around a substantially circular aperture as shown in, and described with reference to, the beam manipulators in at least FIGS. 4 and 5. However, the present embodiments differing from those shown in and described with reference to FIGS. 4 and 5 in featuring slots with a geometric shape at a distal end of the slots.

FIGS. 7A to 7E, and FIGS. 8A and 8B, show the electrically conductive and insulating properties of surfaces within different shapes of slots according to embodiments. The electrically conductive and insulating surfaces, and the slot shapes, shown in FIGS. 7A to 7E, and FIGS. 8A and 8B, may all be made, for example, using the techniques described earlier with reference to FIGS. 6A to 6D. It should be understood that FIGS. 7A to 7E, and FIGS. 8A and 8B, do not show the arrangement of insulator within the substrate, which may be according to any of the patterns shown in FIGS. 6A to 6D and/or other patterns. This is because FIGS. 7A to 7E, 8A and 8B show and exemplify individual slots rather than a series of slots around an aperture. The different surfaces shown and described with reference to FIGS. 7A to 7E and FIGS. 8A and 8B may be defined by the bulk material that defines the corresponding surface. Thus portions of the different designs may be formed by the insulating ring, or features associated with the isolating ring, and by electrodes of bulk material supported by the ring. Examples of this can be seen in FIGS. 6A to 6D which are embodiments for respectively providing the insulating surfaces and slot shapes of FIGS. 7D, 7E, 8A and 8B.

The beam manipulators with electrodes as shown in FIGS. 7A-7E may comprise corresponding features to the beam manipulators described in the previous sections with respect to at least FIGS. 4 and 5. In particular, the beam manipulators with electrodes as shown in FIGS. 7A-7E may comprise: an aperture in the substrate that is a through passage for charged particles; a slot between each pair of adjacent electrodes; and surfaces thereof that extend through the substrate between opposing major surfaces of the substrate.

As shown in FIG. 7A, resulting from the shape of each slot 831, each electrode may comprise one or more protruding portions 815 and 816. Each of the protruding portions 815 and 816 may have a side surface that faces a side surface of a corresponding protruding portion of an adjacent electrode. For example, protruding portion 815 has side surface 826 that faces surface 827 of protruding portion 816. Protruding portion 815 may further have aperture facing surface 821. An end of the aperture facing surface 821 meets side surface 826. Similarly, protruding portion 816 may have an aperture facing surface 822. The aperture facing surfaces 821, 822 may define at least of part of the inner wall of the manipulator, for example the through passage of the manipulator. An end of the aperture facing surface 822 meets side surface 827. A distal end of slot 831 is geometrically shaped such that, in schematic plan view, the slot 831 is a substantial T-shape. The slot 831 is surrounded by multiple surfaces of the adjacent protruding portions 815 and 816. In a corresponding manner to the T-shape slot shown in described with reference to FIGS. 6A and 6B slot 831 is surrounded by, or at least defined by, side surfaces 826 and 827 (that define the stem of the T-shape), a tangentially extending end surface 850 (or radially inwardly facing surface), radially extending surface 851 and tangentially extending surface 852 (or radially outward facing surface) in a left hand bifurcated branch (or a first bifurcated branch) of the T-shape in FIG. 6A, and radially extending surface 854 and tangentially extending surface 853 in a righthand bifurcated branch (or a second bifurcated branch) of the T-shape in FIG. 6A. Surfaces 851, 852, 853, 854 and 850 all extend through substrate from its upper major surface to its lower major surface.

In FIG. 7A, surfaces 852, 851, 850, 854 and 853 are all contiguous surfaces of insulator. Surfaces 822 and 827, e.g. aperture facing surface 822 and side surface 827, are contiguous surfaces of an electrical conductor on protruding portion 816. Surfaces 821 and 826 are contiguous surfaces of an electrical conductor on protruding portion 815. The electrical conductor on protruding portion 816 may be at least part of a first electrode of a beam manipulator and the electrical conductor on protruding portion 815 may be at least part of a second electrode of a beam manipulator. The first and second electrodes may have electrode surfaces: a first electrode surface and a second electrode surface respectively. For example, the aperture facing surface 822 and side surface 827 may define the first electrode surface. The aperture facing surface 822 and side surface 827 may define the first electrode surface. The first electrode surface and the second electrode surfaces respectively extend into the slot. The electrically conductive surfaces of the first and second electrodes may be doped silicon. Thus the electrode surfaces comprise doped substrate. The first and second electrodes of the beam manipulator are electrically isolated from each other by the presence of the slot and at least the insulator surfaces 852, 851, 850, 854 and 853. In this arrangement, the insulator surface individually may be referred to as electrically insulating regions or together as the electrically insulating region. The electrically insulating region extends between the major surfaces 501, 502. The first electrode surface and second electrode surface may define the electrically insulating region. That is a radial outward boundary of each of the first and second electrode surfaces may correspond to a radially inward boundaries of the insulating region. Insulator surfaces 852, 853 may be examples of radially outward facing portions that at least in part define the electrically insulating region. Insulator surfaces 851, 854 may be radially extending portions that at least in part define electrically insulating region. The insulator surfaces 851, 854 that are radially extending portions may face each other, e.g. oppose each other. Insulator surface 850 may be a radially inward facing portion of the electrically insulating region. The insulator surface 850 may face, optionally oppose, each of the insulator surfaces 852, 853 e.g. the radially outward facing portions.

The beam manipulator shown in FIG. 7A differs from that shown in FIGS. 4 and 5 in that the electrically conductive surfaces of the first and second electrodes extend all along the respective side surfaces 827 and 826 for example of the stem of the slots. Embodiments include the design aspect of the beam manipulator design shown in FIGS. 4 and 5 in which the first and second electrodes only extend partially along the respective side surfaces 827 and 826 for example of the stem of the slots. Thus at least part of the electrode surfaces of the electrodes 511, 512 either side of the slot 531, 831 are at least partially defined by the respective side surfaces 826, 827. Thus electrode surfaces are defined by at least a respective side surfaces 826, 827 and inward surfaces. These different embodiments of beam manipulator may be made by adjusting the doping processes for making the electrically conductive surfaces of the first and second electrodes.

In another example that is shown in FIG. 7B, the surfaces of the electrodes and slot between the electrodes differ from those in FIG. 7A only in that the radially extending surface 850 is an electrical conductor instead of an insulator. The surfaces are otherwise the same as described for FIG. 7A. Thus the first electrode surface and the second electrode surface are defined in the same way as the example described with reference to and depicted in FIG. 7A. The electrically conductive surface 850 is electrically isolated from the electrically conductive surfaces 827 and 822 of the first electrode of the beam manipulator at least by the insulator surfaces 852 and 851. In this arrangement, the insulator surfaces individually may be referred to as electrically insulating regions or in the contiguous regions, 851, 852 and 853 and 854 as respective electrically insulating regions. The electrically insulating regions extend between the major surfaces 501, 502. Insulator surfaces 852, 853 may be examples of radially outward facing portions that at least in part define in part the different electrically insulating regions. Insulator surfaces 851, 854 may be radially extending portions that at least in part define the different electrically insulating regions. The insulator surfaces 851, 854 that are radially extending portions may face each other, e.g. oppose each other. The electrically conductive surface 850 is electrically isolated from the electrically conductive surfaces 826 and 821 of the second electrode of the beam manipulator at least by the insulator surfaces 853 and 854. The beam manipulator may be configured so that the electrically conductive surface 850 is at a local ground potential. The electrically conductive surface 850 may be a radially inward facing surface. At least a portion of the electrically conductive surface 850 may define a radial end surface of the stem of the slot. The electrically conductive surface 850 may face, e.g., oppose, the radially outward facing portions of the electrically insulating regions. The electrically insulating region may be configured to electrically isolate electrically conductive surface 850, which is at for example a local ground potential.

The recessed surface may comprise a region between separate adjacent electrodes, for example the first electrode and the second electrode (e.g. the first electrode surface and the second electrode surface) configured to operate at the local ground potential. The electrically conductive surface 950, for example the region at a local ground potential, may extend into an arm, or both arms as depicted. Since the region at the local ground potential may comprise a part that may define the radial end surface of the stem, charged particles from the path of the charged particle beam through the aperture may reach the conductive surface 850. Since the conductive surface is connected to the local ground potential, any charged supplied by any incidental charged particles may be discharged on impact. Charge desirably is directed away and does not build up on the conductive surface. The risk of charge build up on a portion of the recessed surface of the slot may be reduced if not prevented.

In another example that is shown in FIG. 7C, the surfaces between adjacent electrodes differ from those in FIG. 7A only in that the surfaces 852, 851 and 850 are electrically conductive instead of being electrical insulators. The surfaces are otherwise the same as described for FIG. 7A. Accordingly, in the present example, at least one of the two electrode surfaces (i.e. the first electrode surface and the second electrode surface) extends into an arm portion. Surfaces 822, 827, 852, 851 and 850 are contiguous electrically conductive surfaces for example to define the first electrode surface. The first electrode surface may be defined by the aperture facing surface 822, side surface 827, radially outward facing surface 852, radially extending surface 851 and radially inwardly facing surface 850. The radially inward facing surface 850 may be referred to as a distal inward electrode surface of the first electrode. The distance inward electrode surface may be part of the first electrode surface. Thus, distal inward electrode surface 850 may be radially outward of the inner wall 822, 821 with respect to the path. Thus, the first electrode comprises the distal inward electrode surface that is radially outward of the inner wall with respect to the path. The first and second electrodes of the beam manipulator are electrically isolated from each other at least by the insulator surfaces 854 and 853. In this arrangement, the insulator surface 853, 854 individually may referred to as electrically insulating regions or together as the electrically insulating region. The electrically insulating region extends between the major surfaces 501, 502. Insulator surface 853 may be a radially outward facing portion that at least in part defines electrically insulating regions. The electrically insulating region may at least in part be defined by the radially extending portion provided by insulator surface 854.

In another example that is shown in FIG. 7D, the surfaces between adjacent electrodes differ from those in FIG. 7B only in that the surfaces 852 and 853 are electrical conductors instead of an insulator. Accordingly, in the present example, the surfaces 822, 827 and 852 are contiguous surfaces of a conductor on protruding portion 816. The surfaces 821, 826 and 853 are contiguous surfaces of a conductor on protruding portion 815. The electrically conductive radially extending surface 850 is electrically isolated from the first electrode of the beam manipulator at least by the insulator surface 851. The surface 850 is electrically isolated from the second electrode of the beam manipulator at least by the insulator surface 854. In this arrangement, the insulator surface 853, 854 may referred to as electrically insulating regions; these surfaces do not provide a contiguous electrically insulating region. The electrically insulating regions extend between the major surfaces 501, 502. Insulator surfaces 851, 854 may be radially extending portions that each at least in part define different electrically insulating regions. The insulator surfaces 851, 854 that are radially extending portions may face each other, e.g. oppose each other. As for the example shown in FIG. 7B, during operation of the beam manipulator the surface 850 may be at a local ground potential. In the present example, the insulator within the substrate may have the pattern shown in FIG. 6A.

The electrically conductive surface 850 may be a radially inward facing surface. The electrically conductive surface 850 may face, e.g., oppose, the radially outward facing portions of the electrically insulating regions. The electrically insulating regions may be configured to electrically isolate electrically conductive surface 850, which is at for example a local ground potential. Thus the insulating regions defined at least by the radially extending surfaces 851, 854 may be distal from the stem portion of the slot. Thus the recessed surface may comprise a region between separate adjacent electrodes, for example the first electrode and the second electrode (e.g. the first electrode surface and the second electrode surface) configured to operate at the local ground potential. The electrically conductive surface 950, for example the region at a local ground potential, may extend into an arm, or both arms as depicted.

In another example that is shown in FIG. 7E, the surfaces of the adjacent electrodes differ from those in FIG. 7C only in that the surface 853 is an electrical conductor instead of an insulator. The surfaces are otherwise the same as described for FIG. 7C. Accordingly, in the present example, surfaces 822, 827, 852, 851 and 850 are contiguous electrically conductive surfaces. Surfaces 821, 826 and 853 are contiguous electrically conductive surfaces. The first and second electrodes of the beam manipulator are electrically isolated from each other at least by the insulator surface 854. In this arrangement, the insulator surface 854 may referred to as the electrically insulating region. The electrically insulating region extends between the major surfaces 501, 502. Insulator surface 54 may be radially extending portion that at least in part defines electrically insulating region. The electrically insulating region may be at or at least towards the end of an arm portion of the slot. Thus the insulating region defined at least by the radially extending surface 854 may be distal from the stem portion of the slot. In the present example, the insulator within the substrate may have the pattern shown in FIG. 6B.

FIG. 8A shows another example. The example in FIG. 8A differs from those described earlier with reference to FIGS. 7A to 7E by the slot 910, in schematic plan view, having a substantial L-shape (or a shape with a single branch extending from the stem of the slot, desirably at a distal end of the slot, desirably in a direction angled desirable orthogonal to the direction of the stem of the slot). The slot depicted in FIG. 8A is an example of a slot with a single arm portion or angled portion. In other respects, the example in FIG. 8A may be the same as the earlier described embodiments with reference to FIGS. 7A to 7E. In particular, it comprises a substrate aperture that is a through passage for charged particles and, between facing surfaces of adjacent electrodes, part of the slot. The substrate aperture and each slot extend through the substrate between opposing major surfaces of the substrate.

In FIG. 8A, surface 901 is an aperture boundary surface, or aperture facing surface, of a first electrode of a beam manipulator. Surface 902 is a radially extending surface of the first electrode. Surface 903 is a tangentially extending aperture facing surface, i.e. it is inwardly facing. The inward surface 903 may be referred to as a distal inward surface. Surface 904 is a first radially extending surface between the first electrode and a second electrode. Surface 904 is desirably non-conductive; that is surface 904 may be an insulator. Thus, the second electrode surface, extends into the arm portion of the slot. Surface 905 is a tangentially extending surface that faces away from the slot and desirably the aperture, i.e. it is outwardly facing. Surface 905 may be of the second electrode. Surface 906 is side surface for example a second radially extending surface of the second electrode. Surface 907 is an aperture boundary surface of the second electrode.

In FIG. 8A, surfaces 901, 902 and 903 are contiguous surfaces of an electrical conductor. Surface 904 is an insulator. Surfaces 905, 906 and 907 are contiguous surfaces of an electrical conductor on protruding portion 909 of the second electrode. The first electrode surface may be defined by the aperture facing surface 901, side surface 902, and radially inwardly facing surface 903. The second electrode surface may be defined by the aperture facing surface 907, side surface 906, and radially outward facing surface 905. The radially outward facing surface 905 of the second electrode may face, e.g. oppose, the radially inward facing surface 903 of the first electrode surface. The radially inward facing surface 903 may be referred to as the distal inward surface or the distal inward electrode surface of the first electrode. The distance inward electrode surface may be part of the first electrode surface. Thus, distal inward electrode surface 903 may be radially outward of the inner wall 901, 907 with respect to the path. Thus, the first electrode comprises the distal inward electrode surface that is radially outward of the inner wall with respect to the path.

The conductive surfaces may be doped silicon. The first and second electrodes of the beam manipulator are electrically isolated from each other by at least the insulator surface 904. In this arrangement, the insulator surface 904 may referred to as the electrically insulating region. The electrically insulating region extends between the major surfaces 501, 502. Insulator surface 904 may be a radially extending portion that at least in part defines an electrically insulating region. The radially extending portion or the insulator surface 904 may face a part of the radially extending portion of the side surface 902 of the first electrode surface. Thus the insulating region defined at least by the radially extending surface 904 may be distal from the stem portion of the slot. In the present example, the pattern of insulator used to form the surface 904 may be that shown in FIG. 6C. The slot 910 may be referred to as “L-shaped”. That is to say, in plan view, the slot 910 has a tangential extension to the slot at remote end of the slot relative to the aperture or through passage.

Embodiments also include a number of variations to the implementation shown in FIG. 8A. In a first variation, surfaces 903 and 905 are insulators and the other surfaces are as shown in FIG. 8A. In a second variation, surfaces 903 and 905 are insulators, surface 904 is a grounded electrode, and the other surfaces are as shown in FIG. 8A. In a third variation, surface 905 is an insulator, surface 904 is part of the same conductive surface as 903s, and the other surfaces are as shown in FIG. 8A. In a fourth variation, surface 903 is an insulator, surface 904 is part of the same conductive surface as 905, and the other surfaces are as shown in FIG. 8A. Embodiments also include further variations to those described above. In preferred implementations, the surface 903 is conductive. Surface 903 may be either grounded or at the same potential as one of the electrodes. This may allow the stem of the slot to be shorter than with other implementations that have the same performance level.

FIG. 8B shows another example. The example in FIG. 8B differs from that shown in at least FIG. 8A by the slot 922, in schematic plan view, having a substantial J-shape. That is to say, in plan view, in addition to the tangential extension to the L-shaped slot, there is a radially inward extension to the tangential extension at the distal end of the tangential extension. The slot depicted in FIG. 8B is an example of a slot with a single arm portion or angled portion with a secondary portion. In other respects, the example in FIG. 8B may be the same as at least the example shown in FIG. 8A. (A J-shape of slot may be shaped (as an L shape) to have a single branch extending from the stem of the slot, desirably at a distal end of the slot, desirably in a direction angled desirable orthogonal to the direction of the stem of the slot, and a secondary or further branch. The secondary branch may extend at an angle from the branch desirably at a distal end of the branch and desirably in a direction substantially orthogonal to the branch optionally in an opposite direction to the stem).

In FIG. 8B, surface 911 is an aperture boundary surface, or aperture facing surface, of a first electrode of a beam manipulator. Surface 912 is a radially extending surface of the first electrode. Surface 913 is a tangentially extending aperture facing surface, i.e. it is inwardly facing. Desirably surface 913 is non-conductive, desirably surface 913 is an insulator for example an insulating surface. Surface 913 is between the first electrode and a second electrode. Surface 913 may be in a secondary portion of the slot. Surface 913 may be referred to as a distal inward facing surface. Surface 914 is a first radially extending surface of a second electrode. Surface 915 is first a tangentially extending surface that faces away from the aperture, i.e. it is outwardly facing; surface 916 may be referred to as radially outward facing surface. Surface 916 is a second radially extending surface of the second electrode. The secondary portion may at least be defined by surfaces 915, 916 and at least part of surface 914. The surfaces of the secondary portion may be defined by an insulating surface and at least portions of the surface of the first electrode and the second electrode. Surface 917 is a second tangentially extending surface that faces away from the aperture, i.e. it is outwardly facing; so surface 917 may be referred to as an outward facing surface). Surface 918 is a third radially extending surface of the second electrode. Surface 919 is an aperture boundary surface of the second electrode.

In FIG. 8B, surfaces 911, 912, 913 and 914 are contiguous surfaces of an electrical conductor. Surface 915 is an insulator. Surfaces 916, 917, 918 and 919 are contiguous surfaces of an electrical conductor on protruding portion 920. Portion 921 is at least part of the first electrode. Protruding portion 920 is at least part of the second electrode. The first electrode surface may be defined by the aperture facing surface 911, side surface 912, radially inwardly facing surface 913 and the first radially extending surface 914. The second electrode surface may be defined by the aperture facing surface 919, side surface 918 (or third radially extending surface), radially outward facing surface 917 and radially extending surface 916 (or second radially extending surface). The radially outward facing surface 917 of the second electrode and the insulating radially outward facing surface 915 may each face, e.g. oppose, the radially inward facing surface 913 of the first electrode The radially extending surface 915 of the first electrode may face, e.g. oppose, at least part of the side surface 912, desirably a distal portion of the side surface 912 of the first electrode, and the radially extending surface 916 of the second electrode. Thus the insulating region defined at least by the radially outward facing surface 915 may be distal from the stem portion of the slot. The electrically conductive surfaces may be doped silicon. The first and second electrodes of the beam manipulator are electrically isolated from each other by at least the insulator surface 915. In this arrangement, the insulator surface 915 may referred to as electrically insulating region. The electrically insulating region extends between the major surfaces 501, 502. Insulator surface 915 may be examples of radially outward facing portions that at least in part defines an electrically insulating region. The insulator surface 915 may define a surface or at least part of a secondary portion of the slot 922. The secondary portion of the slot may be considered to be a portion of the recessed surface, such as an end portion of the recessed surface, that extends radially inwardly. In the present example, the pattern of insulator used to form the surface 915 may be that shown in FIG. 6D.

Embodiments also include a number of variations to the implementation shown in FIG. 8B. For example, surfaces 916 and/or 914 may be insulator instead of, or in addition to, surface 915. In preferred implementations, the surface 913 is conductive. Surface 913 may be either grounded or at the same potential as one of the electrodes.

The electrically conductive and insulating surfaces of all of the designs of beam manipulator shown in FIGS. 7A to 8B may be made using at least the techniques described with reference to FIGS. 6A to 6D. That is to say, the insulating surfaces may be made by forming pattern of insulator within a substrate. The electrically conductive surfaces may be doped substrate that is made by doping exposed substrate surfaces. An advantage of this method of manufacture is that it allows the manufacture of beam manipulators that cannot be manufactured, or are difficult to manufacture, using other techniques.

In FIGS. 7A to 7E and FIGS. 8A and 8B, each slot comprises recessed surfaces between separate adjacent electrodes.

Each electrode comprises electrode surfaces. For each electrode, at least one electrode surface provides an aperture boundary surface along the aperture in the substrate that is a through passage for charged particles. The aperture boundary surfaces are surfaces 821, 822, 901, 907, 911 and 919. The aperture boundary surfaces all extend from the upper major surface to the lower major surface of the substrate.

The recessed surfaces of each slot may comprise one or more further electrode surfaces extending from a boundary surface and, optionally, extending over different surfaces defined by the geometric shape of the slot. All of the electrode surfaces may extend from the upper major surface to the lower major surface of the substrate.

The recessed surfaces of each slot may comprise at least one surface that is at a local ground potential and electrically isolated from the boundary surfaces of the electrodes.

The recessed surfaces of each slot may comprise one or more electrically insulating regions. The electrically insulating regions may extend over different surfaces defined by the geometric shape of the slot. All of the electrically insulating regions may extend between the upper major surface and lower major surface of the substrate.

Each electrically insulating region may extend between metallic surfaces, i.e. an electrode or a surface at a local ground potential.

The recessed surfaces may comprise a radially outward facing surfaces, i.e, surfaces 852, 853, 905, 917 and 915. The recessed surfaces may comprise a radially inward facing surfaces, i.e, surfaces 850, 903, and 913.

The recessed surfaces may be defined with respect to the shape of the slot. The recessed surfaces that comprise a stem portion are surfaces of the stem of the slot, i.e, surfaces 827, 826, 902, 906, 912 and 918. The recessed surfaces that comprise a stem portion may all be comprised by the electrodes. The recessed surfaces that comprise a tangential portion are surfaces of the tangential sections of the slot and the parts extending therefrom, i.e, surfaces 852, 851, 850, 854, 853, 903, 904, 905, 913, 914, 915, 916 and 917.

In FIGS. 7A to 7E, the tangential portions of the slot bifurcate in opposing tangential directions. In FIG. 8A the tangential portion of the slot extends in only one tangential direction. In FIG. 8B the tangential portion of the slot extends in a tangential direction and a radially inward directed portion extends therefrom.

Embodiments include providing a beam manipulator with the electrodes, and slots between adjacent electrodes, as described above with reference to FIGS. 5A to 5D, FIGS. 7A to 7E and FIGS. 8A and 8B applied around a respective beam path or sub-beam path, for example arranged in a circle. Each beam manipulator may comprise, for example, four, eight twelve electrodes, or any number of electrodes being a multiple of four.

Embodiments also include providing a beam manipulator array comprising a plurality of beam manipulators according to embodiments.

A general goal is to increase the density of beam manipulators in beam manipulator arrays. This requires reducing the sizes of each of the manipulators in the array. The size of the beam manipulators shown in FIG. 7A is restricted by a requirement on the ratio of the width to the length of the slot between adjacent electrodes. An approximate ratio of 1:5 may need to be maintained. The minimum width of the slot is substantially fixed due to manufacturing restrictions. Due to the requirement to maintain the 1:5 ratio, the minimum width of the slot imposes a restriction on the minimum length of the slot. The lengths of the slot thereby determine a minimum size of the beam manipulators that beam manipulators cannot be decreased beyond with the 1:5 ratio being maintained.

An advantage of beam manipulators with electrodes according to the embodiments shown in FIGS. 7B to 7E, and FIGS. 8A and 8B, is that they may allow the requirement to maintain a 1:5 ratio to be relaxed. The ratio of the closest tangential distance between adjacent electrodes to the radial length of part of the slot that extends from the aperture may be reduced to less than 1:5. For example the ratio may be 1:3 or lower.

This relaxation of the 1:5 ratio allows the radial extent of slots extending from an aperture to be decreased and thereby a size reduction of a beam manipulator. The density of beam manipulators in the beam manipulator array can thereby be increased.

A feature of the electrode designs shown in FIGS. 7B to 7E, and FIGS. 8A and 8B, that may allow the 1:5 ratio to be relaxed is the size and location of the non-conducting surfaces between adjacent electrodes. The non-conducting surfaces may catch electrons such that there is a charge build-up over time. This charge build-up disturbs the performance of other parts of the structure. In all of the electrode designs shown in FIGS. 7B to 7E, and FIGS. 8A and 8B, the amount of non-conducting surface is less than in FIG. 7A. In addition, the exposed non-conducting surfaces are shielded from a charged particle beam, such as an electron beam, traveling through the substrate aperture. That is to say, the geometric shape of the slot substantially, and/or entirely, prevents line-of-sight paths between the substrate aperture and the non-conducting surfaces. The build-up of charge on the non-conducting surfaces may thereby be reduced.

The more remote the electrically insulating region is from the stem portion of the slot, the better the shielding of the insulating regions and the respective apertures. For example having the electrically insulating region distal from the stem portion as shown and described with reference to FIGS. 7D, 7E, 8A and 8B may provide improved shielding. Further, having the electrically insulating region distal provided by a tangentially extending surface distal from the stem portion, for example within a secondary portion, such as part of a J-shape slot, for example as shown in and described with reference to FIG. 8B may provide improved shielding as compared to other designs of slot for example as shown and described with reference to FIGS. 7D, 7E and 8A, such as T-shaped or L-shaped slots. Manipulators with better shielding are less likely to have the isolating regions influence the path of the charged particle beam through the respective aperture of the manipulator, for a given radial length of slot. Therefore the radial slot length of manipulator embodiments with better shielding may be smaller than the slot length of other manipulators. This enables manipulators of designs with more improved shielding to be in manipulator arrays having a higher density of manipulators. The density of sub-beams of the multi-beam of charged particles may be greater for a manipulator with more improved shielding or a short slot length.

In particular, a feature of the electrode designs shown in FIGS. 7B to 7E, and FIGS. 8A and 8B, is that, compared to the electrode design in at least FIG. 7A, a different material is used for the aperture facing surfaces 850, 903 and 913. These surfaces are metalized so that they are either contiguous with a surface of an electrode or at a local ground potential. The 1:5 ratio may be relaxed both due to the size of the non-conducting surfaces being reduced and the location of the non-conducting surfaces.

Each beam manipulator with electrodes and slots according to the embodiments shown in FIGS. 7B to 7E, and FIGS. 8A and 8B, may therefore have a smaller radial extent of slot from a substrate aperture whilst achieving comparable performance to a beam manipulator with an electrode as shown in FIG. 7A). Indeed relative to the arrangement shown and described with reference to FIGS. 4 and 5, the arrangement shown and described with reference to FIG. 7A may have a smaller radial extent of slot from a substrate aperture and yet achieve comparable performance when present in a beam manipulator. This allows the size of the beam manipulators to be reduced. The beam manipulators are therefore particularly suited to use in dense beam manipulator arrays in which the pitch, i.e, separation, between adjacent beam manipulators is small.

Features of the slot arrangements shown and described with respect to FIGS. 7A to 7E, 8A and 8B may be combined in different combinations. Each of the slots may have curved surfaces, curved edges, or distinct corners. The slots may have a tangential position (such as a T-shaped bifurcated arm). The slots may have at least one curved portion. A distal portion may have a greater tangential portion than a proximate portion of the slot (e.g., the length of the bifurcated arm of T-shape may be higher than the length of the central stem section of T-shape). Variations of the slot arrangement may take on other variations and alterative embodiments of those disclosure and described with reference to FIGS. 7A to 7D, 8A and 8B as herein elsewhere described. For example the arm portions of a slot need not be located at the distal end of the slot. The arm portions may be spaced away from the distal portion, for example within a distal half of the slot. The arm portions need not be tangential, for example have a direction orthogonal to the direction in which the slot extends. For example an arm portion may be angled with respect to the slot. A slot need not have two arms but as many or as few arms as desired. For example a slot may have a single arm or angled portion. The arms portions of a slot with multiple arm portions may be angled differently with respect to the slot. For example a slot may have two arm portions of which one arm portion is tangential.

According to embodiments of the present disclosure, the electrically insulating region comprises a radially outward facing portion, desirably with respect to the path of the charged particle beam for example a sub-beam. The electrically insulating region comprises at least one radially extending portion desirably with respect to the path of the charged particle beam e.g, sub-beam and optionally two radially extending portions that face each other. The electrically insulating region is configured to electrically isolate a region configured to operate at a local ground potential and, optionally, the local ground potential is a radially inward facing surface desirably with respect to the path of the charged particle beam such as sub-beam. The recess (which may be referred to as recessed surface) comprises a stem portion and a substantially angled, desirably tangential, portion, desirably with respect to the path of the charged particle beam e.g. a sub-beam. The recessed surface comprises two angled portions at a distal end of the stem portion. At least one of the angled portions may be a tangential portion with respect to the path. The angled portion comprises a secondary portion. The secondary portion is angled towards a proximate electrode, desirably a most proximate electrode, of the plurality of electrodes. Desirably the secondary portion is orthogonal to the tangential portion. Desirably the secondary portion is parallel to the stem portion. The insulating region defines a surface of the substantially tangential portion, with respect to the path, extending between the major surfaces. Desirably the insulating region defines a surface of the secondary portion extending between the major surfaces. The electrodes surfaces that define the insulating region extend into the tangential portion desirably the secondary portion. The electrically insulating region is a surface of the tangential portion, desirably with respect to the path, distal from the stem portion such that the insulating region is shielded from the stem portion. The recessed surface comprises an end portion extending radially inwardly, with respect to the path. The recessed surface comprises a region between the separate adjacent electrodes configured to operate at a local ground potential. Desirably the local ground potential at least has an end in an angled portion (desirably with respect to the path) desirably is within a tangential portion. The substrate may be silicon. Each electrode maybe doped silicon. Each electrically insulating region may be silicon oxide.

According to embodiments of the present disclosure, one or more charged particle beams may be manipulated by electric fields generated by a beam manipulator. To generate electric fields to affect trajectories of one or more beams passing through an aperture in the beam manipulator, the electrodes of the beam manipulator may be wired individually or collectively to a corresponding power source, which may be generally positioned outside of an electron column of SEM or at least a vacuum chamber of the column such as the scanning device. In some embodiments, electric circuits configured to provide a driving voltage or control signal to the electrodes may be formed on the upper and/or lower major surfaces of the substrate. In arrangement, the body of the substrate may function as an electrode, and no routing is provided.

A beam manipulator including, for example, four electrodes may be configured in different ways to function differently. When all four electrodes are applied to one voltage potential, the beam manipulator can function as a micro-lens. When the two pairs of opposite electrodes are applied to two voltages of the same absolute value but opposite polarity, the beam manipulator can function as a micro-stigmator. When (i) one pair of opposite electrodes are applied to a zero voltage, and (ii) the other pair of opposite electrodes are applied to two voltages of the same absolute value but opposite polarity, beam manipulator can function as a micro-deflector.

A magnitude or polarity of a voltage applied to each of the electrodes may be determined according to a target manipulation direction or manipulation degree of a charged particle beam passing through the aperture that the electrodes are arranged around. In some embodiments, a controller (such as controller 50 of FIG. 2) may be configured to control voltage levels, voltage polarities, voltage application timing, etc, for each electrode included in beam manipulator.

Embodiments include a number of modifications and variations to the techniques described above.

A beam manipulator according to some embodiments may have a single electrode. The single electrode may have a substantial hollow cylinder shape surrounding the electron aperture. In some embodiments, the beam manipulator may not include a slot. The internal surface of the hollow cylinder-shaped electrode may define the electron aperture. The electron aperture may extend from the upper major surface to the lower major surface of the substrate. In some embodiments, the beam manipulator may include a slot, such as slot 531 as shown in FIG. 4, separating two ends of the same electrode.

An array of beam manipulators according to embodiments may be used to simultaneously manipulate each sub-beam of a multi-beam of charged particles in a charged particle beam illumination apparatus (that may also be referred to as a charged particle illumination apparatus or a multi-beam charged particle illumination apparatus).

The geometry of a manipulator of for example its constituent through passage and apertures may be defined with respect to the path of a beam (or sub-beam) that passes through the manipulator or an axis of the manipulator which is parallel to the central axis. The path of the beam and the axis of the manipulator may correspond to each other for example if the manipulator is a macro manipulator positioned to operate on a single beam or all sub-beams of a multi-beam. The path of the sub-beam corresponds to the axis manipulator when the manipulator is positioned in a central location in the manipulator array, or the manipulator is any manipulator in the manipulator array when the manipulator array is at position of the multibeam path towards the sample at which the sub-beams are substantially collimated and so desirably parallel to the central axis.

Therefore the terms ‘radial’ “outward” “inward” and the like, at least with respect to a manipulator or a feature thereof such as of a slot or surface of a slot, is intended to be with respect to the path of the sub-beam though the manipulator and/or the manipulator axes, unless stated to contrary.

Reference to a component or system of components or elements being controllable to manipulate a charged particle beam in a certain manner includes configuring a controller or control system or control unit to control the component to manipulate the charged particle beam in the manner described, as well optionally using other controllers or devices (e.g. voltage supplies) to control the component to manipulate the charged particle beam in this manner. For example, a voltage supply may be electrically connected to one or more components to apply potentials to the components, such as to the electrodes 511, 512, 513, 514 of the manipulators 590 for example of the manipulator array 500, under the control of the controller or control system or control unit. An actuatable component, such as a stage, may be controllable to actuate and thus move relative to another components such as the beam path using one or more controllers, control systems, or control units to control the actuation of the component.

An assessment tool or assessment system according to the disclosure may comprise apparatus which makes a qualitative assessment of a sample (e.g, pass/fail), one which makes a quantitative measurement (e.g. the size of a feature) of a sample or one which generates an image of map of a sample. Examples of assessment tools or systems are inspection tools (e.g, for identifying defects), review tools (e.g, for classifying defects) and metrology tools, or tools capable of performing any combination of assessment functionalities associated with inspection tools, review tools, or metrology tools (e.g. metro-inspection tools).

The charged particle beam illumination apparatus could be a component of an assessment system such as an inspection or metrology system or part of an e-beam lithography tool or system. The charged particle apparatus according to embodiments may be used in a number of different applications that include electron microscopy in general, not just SEM such as for sample assessment, and lithography.

In particular, the charged particle column such as the beam illumination apparatus and/or the scanning device may comprise one or more beam manipulators according to embodiments and any of the components of the apparatuses described above with reference to FIGS. 1 to 3.

The charged particle beam illumination apparatus may comprise a single source of charged particles, as shown in FIGS. 1 to 3. Alternatively, the charged particle beam illumination apparatus may comprise a plurality of sources of charged particles. There may be a separate column for each source and an array of beam manipulators according to embodiments provided in each column. Alternatively, the charged particle beam illumination apparatus may comprise a plurality of sources of charged particles and only a single column. An array of beam manipulators according to embodiments may be provided in the single column.

Embodiments include a manipulator for manipulating a charged particle beam in a charged particle column which may comprise a projection system, the manipulator defined in a planar body having two major surfaces, the manipulator comprising: an aperture surface that defines at least part of an aperture that extends between the major surfaces, the aperture surface being for passage of the charged particle beam to pass therethrough; a radially extending surface defining at least part of a slot that extends between the major surfaces and radially from the aperture, wherein the radially extending surface extends from the aperture surface at a proximal end of the radially extending surface; an outward facing surface extending between the major surfaces and from the radially extending surface at a distal end of the radially extending surface; and an inward facing surface extending between the major surfaces, wherein the inward facing surface faces the outward facing surface at a portion of the slot that is distal from the aperture; wherein the manipulator comprises an electrode defined by an electrically conducting surface of the aperture surface, and an electrically insulating region adjoining (or adjacent) the electrically conducting surface and extending between the major surfaces within the slot.

Embodiments also include a manipulator for manipulating a charged particle beam in charged particle column which may comprise a projection system, the manipulator comprising: a substrate having opposing major surfaces in each of which is defined an aperture and a through-passage having an interconnecting surface extending between the apertures; wherein the interconnecting surface comprises: a plurality of electrodes; at least one recessed surface, each recessed surface being between separate adjacent electrodes, the recessed surface being recessed into the substrate deeper than the adjacent electrodes to provide an electrically insulating region extending between the opposing major surfaces and enabling electrical insulation between the adjacent electrodes.

Embodiments also include the following numbered clauses.

Clause 1: A manipulator for manipulating a charged particle beam in a charged particle column which may comprise a projection system, the manipulator comprising: a substrate having opposing major surfaces in each of which is defined an aperture and a through-passage having an interconnecting surface extending between the apertures; wherein the interconnecting surface comprises: a plurality of electrodes; at least one recessed surface; wherein each recessed surface is between separate adjacent electrodes and comprises: electrode surfaces extending from each of the separate adjacent electrodes that the recessed surface is defined between, and an electrically insulating region extending between the major surfaces and enabling electrical insulation between the electrode surfaces of the adjacent electrodes; wherein: the recessed surface comprises a region between the separate adjacent electrodes configured to operate at a local ground potential; at least one of the electrode surfaces has a portion which faces radially outward and/or radially inwardly; and/or the electrically insulating region only comprises surfaces facing radially outwardly and/or extending radially; and wherein, optionally, the plurality of electrodes comprise doped substrate.

Clause 2: The manipulator according to clause 1, wherein the electrically insulating region extends between the electrode surfaces.

Clause 3: The manipulator according to clause 1 or 2, wherein the recessed surface is recessed into the substrate deeper than the electrodes.

Clause 4: The manipulator according to any preceding clause, wherein at least one of the electrode surfaces comprises a radially outward facing surface.

Clause 5: The manipulator according to any preceding clause, wherein both of the electrode surfaces comprise a radially outward facing surface.

Clause 6: The manipulator according to any preceding clause, wherein one of the electrode surfaces comprises a radially inwardly facing surface.

Clause 7: The manipulator according to any preceding clause, wherein one of the electrode surfaces comprises two portions that face each other.

Clause 8: The manipulator according to any preceding clause, wherein the electrically insulating region comprises at least one radially extending portion.

Clause 9: The manipulator according to any preceding clause, wherein the electrically insulating region comprises two radially extending portions that face each other.

Clause 10: The manipulator according to any preceding clause, wherein the electrically insulating region comprises a radially outward facing portion.

Clause 11: The manipulator according to any preceding clause, wherein the electrically insulating region comprises only radially outward and/or radially extending portions.

Clause 12: The manipulator according to any preceding clause, wherein the electrically insulating region is configured to electrically isolate a region configured to operate at a local ground potential and, optionally, the local ground potential is a radially inward facing surface.

Clause 13: The manipulator according to any preceding clause, wherein the recessed surface comprises a stem portion and a tangential portion.

Clause 14: The manipulator according to clause 13, wherein the electrically insulating region is a surface of the tangential portion distal from the stem portion such that the insulating region is shielded from the stem portion.

Clause 15: The manipulator according to clause 13 or 14, wherein one of the electrode surfaces comprises a region of the stem portion and an adjoining region (or an adjacent region) of the tangential portion, the region of the tangential portion being a radially inwardly facing surface.

Clause 16: The manipulator according to clause 13 or any clause dependent thereon, wherein the tangential portion bifurcates in opposing tangential directions.

Clause 17: The manipulator according to clause 13 or any clause dependent thereon, wherein the tangential portion extends in only one tangential direction.

Clause 18: The manipulator according to any preceding clause, wherein the recessed surface comprises an end portion extending radially inwardly.

Clause 19: The manipulator according to clause 18, wherein the electrically insulating region is located in the end portion.

Clause 20: The manipulator according to clause 18 or 19, wherein the end portion is shielded from the stem portion.

Clause 21: The manipulator according to any preceding clause, wherein the electrode surfaces are electrically conductive doped regions.

Clause 22: The manipulator according to any preceding clause, wherein, in plan view, each recessed surface between adjacent electrodes is substantially T-shaped.

Clause 23: The manipulator according to any of clauses 1 to 21, wherein, in plan view, each recessed surface between adjacent electrodes is substantially L-shaped.

Clause 24: The manipulator according to any of clauses 1 to 21, wherein, in plan view, each recessed surface between adjacent electrodes is substantially J-shaped.

Clause 25: The manipulator according to any preceding clause, wherein the substrate is silicon, each electrode is doped silicon, and each electrically insulating region is silicon oxide.

Clause 26: The manipulator according to any preceding clause, wherein the number of electrodes is 4 or 8.

Clause 27: A manipulator for manipulating a charged particle beam in a charged particle column which may comprise a projection system, the manipulator comprising: a substrate having opposing major surfaces in each of which is defined an aperture and a through-passage having an interconnecting surface extending between the apertures, wherein the interconnecting surface comprises: a plurality of electrodes; and at least one recessed surface, each recessed surface being between separate adjacent electrodes, the recessed surface being recessed into the substrate deeper than the electrodes to provide an electrically insulating region extending between the major surfaces and enabling electrical insulation between the adjacent electrodes; wherein: the recessed surface comprises a region between separate adjacent electrodes that is configured to operate at a local ground potential; and/or a surface of each adjacent electrode extends from the apertures and forms part of the recessed surface and the recessed surface is configured so that the electrically insulating region is shielded from each portion of the surface of each adjacent electrode that adjoins (or is adjacent to) the electrode.

Clause 28: A manipulator for manipulating a charged particle beam in a charged particle column which may comprise a projection system, the manipulator formed in a body of a substrate having two major surfaces, the manipulator comprising: an electrode having an aperture facing surface that extends between the two major surfaces and that defines a boundary of an aperture configured for passage of the charged particle beam to pass therethrough; a first surface of the substrate extending radially away from the aperture and defining at least part of a slot which is also extending radially away from the aperture; a second surface of the substrate located in the substrate, wherein the first surface meets the aperture facing surface of the electrode at a first end of the first surface, and the first surface meets the second surface of the substrate at a second end of the first surface; a third surface of the substrate located in the substrate, wherein the second surface meets the first surface of the substrate at a first end of the second surface, and the second surface meets a first end of the third surface of the substrate at a second end of the second surface; an electrically conductive doped region formed on the aperture facing surface of the electrode and at least a part of the first surface of the substrate; and an electrically insulating region formed either on the second surface or on the third surface that enables an electrical isolation of the electrode.

Clause 29: The manipulator according to clause 28, wherein the electrode is a first electrode and the manipulator further comprises: a second electrode having an aperture facing surface that extends between the two major surfaces and that defines a boundary of the aperture; and a fourth surface, a fifth surface, a sixth surface and a seventh surface; wherein: the first to seventh surfaces form a substantially T-shaped slot between the first electrode and the second electrode; the first surface is a surface on a first side of the stem of the substantially T-shaped slot; the second surface is substantially orthogonal to the first surface and extends away from the stem of the T-shaped slot; the third surface is substantially orthogonal to the second surface and extends radially away from the aperture; the seventh surface of the substrate extends radially away from the aperture and is a surface on a second side of the stem of the substantially T-shaped slot; the sixth surface of the substrate is located in the substrate, wherein the seventh surface meets the aperture facing surface of the second electrode at a first end of the seventh surface, and the seventh surface meets the sixth surface of the substrate at a second end of the seventh surface, and the sixth surface is substantially orthogonal to the seventh surface and extends away from the stem of the T-shaped slot; a fifth surface of the substrate located in the substrate, wherein the sixth surface meets the seventh surface of the substrate at a first end of the sixth surface, and the sixth surface meets a first end of the fifth surface of the substrate at a second end of the sixth surface, and the fifth surface is substantially orthogonal to the sixth surface and extends radially away from the aperture; and the fourth surface of the substrate extends between a second end of the third surface and a second end of the fifth surface.

Clause 30: The manipulator according to clause 29, wherein: the first surface comprises an electrically conductive doped region; the seventh surface comprises an electrically conductive doped region; and the second surface, the third surface, the fourth surface, the fifth surface and the sixth surface each comprise an electrically insulating region.

Clause 31: The manipulator according to clause 29, wherein: the first surface, the second surface, the third surface and the fourth surface comprise an electrically conductive doped region; the seventh surface comprises an electrically conductive doped region; and the fifth surface and sixth surface each comprise an electrically insulating region.

Clause 32: The manipulator according to clause 29, wherein: the first surface, the second surface, the third surface and the fourth surface comprise an electrically conductive doped region; the sixth surface and the seventh surface comprise an electrically conductive doped region; and the fifth surface comprises an electrically insulating region.

Clause 33: The manipulator according to clause 29, wherein: the first surface and the second surface each comprises an electrically conductive doped region; the fourth surface comprises an electrically conductive doped region; the sixth surface and the seventh surface comprises an electrically conductive doped region; the third surface comprises an electrically insulating region; and the fifth surface comprises an electrically insulating region.

Clause 34: The manipulator according to clause 29, wherein: the first surface comprises an electrically conductive doped region; the fourth surface comprises an electrically conductive doped region; the seventh surface comprises an electrically conductive doped region; and the second surface, the third surface, the fifth surface and the sixth surface each comprise an electrically insulating region.

Clause 35: The manipulator according to clause 33 or 34, wherein the fourth surface is configured to be at a ground potential.

Clause 36: The manipulator according to clause 28, wherein the electrode is a first electrode and the manipulator further comprises: a second electrode having an aperture facing surface that extends between the two major surfaces and that defines a boundary of the aperture; and a fourth surface and a fifth surface; wherein: the first to fifth surfaces form a substantially L-shaped slot between the first electrode and the second electrode; the first surface is a surface on a first side of the stem of the substantially L-shaped slot; the second surface is substantially orthogonal to the first surface and extends towards the stem of the L-shaped slot; the third surface is substantially orthogonal to the second surface and extends radially away from the aperture; the fifth surface of the substrate extends radially away from the aperture and is a surface on a second side of the stem of the substantially L-shaped slot; a fourth surface of the substrate located in the substrate, wherein the fifth surface meets the aperture facing surface of the second electrode in one end, and meets the fourth surface of the substrate in the other end, and the fourth surface is substantially orthogonal to the fifth surface and extends away from the stem of the L-shaped slot; the third surface of the substrate extends between an end of the second surface and an end of the fourth surface; the first surface and the second surface comprise an electrically conductive doped region; the fourth surface and the fifth surface comprise an electrically conductive doped region; and the third surface comprises an electrically insulating region.

Clause 37: The manipulator according to clause 28, wherein the electrode is a first electrode and the manipulator further comprises: a second electrode having an aperture facing surface that extends between the two major surfaces and that defines a boundary of the aperture; and a fourth surface, a fifth surface, a sixth surface and a seventh surface; wherein: the first to seventh surfaces form a substantially J-shaped slot between the first electrode and the second electrode; the first surface is a surface on a first side of the stem of the substantially J-shaped slot; the second surface is substantially orthogonal to the first surface and extends towards the stem of the J-shaped slot; the third surface is substantially orthogonal to the second surface and extends radially away from the aperture; the seventh surface of the substrate extends radially away from the aperture and is a surface on a second side of the stem of the substantially J-shaped slot; a sixth surface of the substrate located in the substrate, wherein the seventh surface meets the aperture facing surface of the second electrode in one end, and meets the sixth surface of the substrate in the other end, and the sixth surface is substantially orthogonal to the seventh surface and extends away from the stem of the J-shaped slot; a fifth surface of the substrate located in the substrate, wherein the sixth surface meets the seventh surface of the substrate in one end, and meets the fifth surface of the substrate in the other end, and the fifth surface is substantially orthogonal to the sixth surface and extends radially away from the aperture; the fourth surface of the substrate that extends between an end of the third surface and an end of the fifth surface; the first surface, the second surface and the third surface each comprise an electrically conductive doped region; the fifth surface, sixth surface and seventh surface each comprise an electrically conductive doped region; and the fourth surface comprises an electrically insulating region.

Clause 38: The manipulator according to any of clauses 28 to 37, wherein the substrate is silicon, each doped region is doped silicon, and each electrically insulating region is silicon oxide.

Clause 39: The manipulator according to any of clauses 28 to 38, wherein the number of electrodes is 4 or 8.

Clause 40: A manipulator for manipulating a charged particle beam in a charged particle column which may comprise a projection system, the manipulator formed in a body of a substrate having two major surfaces, the manipulator comprising: a first electrode having an aperture facing surface that extends between the two major surfaces and that defines a boundary of an aperture configured for passage of the charged particle beam to pass therethrough; a second electrode having an aperture facing surface that extends between the two major surfaces and that defines a boundary of the aperture; a first surface of the substrate extending radially away from the aperture and defining at least part of a slot which is also extending radially away from the aperture; a second surface of the substrate located in the substrate, wherein the first surface meets the aperture facing surface of the electrode at a first end of the first surface, and the first surface meets the second surface of the substrate at a second end of the first surface; a third surface of the substrate located in the substrate, wherein the second surface meets the first surface of the substrate at a first end of the second surface, and the second surface meets a first end of the third surface of the substrate at a second end of the second surface; a fourth surface, a fifth surface, a sixth surface and a seventh surface; wherein: the first to seventh surfaces form a substantially J-shaped slot between the first electrode and the second electrode; the first surface is a surface on a first side of the stem of the substantially J-shaped slot; the second surface is substantially orthogonal to the first surface and extends towards the stem of the J-shaped slot; the third surface is substantially orthogonal to the second surface and extends radially away from the aperture; the seventh surface of the substrate extends radially away from the aperture and is a surface on a second side of the stem of the substantially J-shaped slot; a sixth surface of the substrate located in the substrate, wherein the seventh surface meets the aperture facing surface of the second electrode in one end, and meets the sixth surface of the substrate in the other end, and the sixth surface is substantially orthogonal to the seventh surface and extends away from the stem of the J-shaped slot; a fifth surface of the substrate located in the substrate, wherein the sixth surface meets the seventh surface of the substrate in one end, and meets the fifth surface of the substrate in the other end, and the fifth surface is substantially orthogonal to the sixth surface and extends radially away from the aperture; the fourth surface of the substrate that extends between an end of the third surface and an end of the fifth surface; the first surface, the second surface and the third surface each comprise an electrically conductive region; the fifth surface, sixth surface and seventh surface each comprise an electrically conductive region; and the fourth surface comprises an electrically insulating region.

Clause 41: A manipulator comprising an array of manipulators of any of claims 1 to 40, desirably wherein the substrate in which each manipulator of the manipulator array is comprised is the same substrate.

Clause 42: A charged particle column, which may comprise a charged particle projection system, the charged particle column comprising a manipulator according to any of clauses 1 to 40 or a manipulator array of clauses 41.

There is provided a number of further clauses which may embody the invention:

Further clause 1. A manipulator for manipulating a charged particle beam, the manipulator comprising a (planar) substrate with major surfaces and a through-passage that defines associated apertures of the ends of the through-passage in the major surfaces, the through passage configured for passage of a path of a charged particle beam, an inner wall of the through-passage between the major surfaces comprising a plurality of electrodes configured to manipulate the charged particle beam, each electrode comprising doped substrate, the through-passage further comprising recesses that extend(s) away from the path of the charged particle beam (optionally a central axis of the through-passage) for isolating individual or adjacent electrodes, each recess defining a gap between the adjacent electrodes (preferably the doped surface of adjacent electrodes) and further comprising an electrically insulating region between the adjacent electrodes wherein the recess extends behind at least one of the adjacent electrodes relative to the path of the charged particle beam and comprising at least part of the electrically insulating region, desirably all of the insulating region.

Further clause 2. The manipulator of further clause 1, wherein the electrically insulating region comprises a radially outward facing portion, desirably with respect to the path of the charged particle beam.

Further clause 3. The manipulator of further clause 1 or, wherein the electrically insulating region comprises at least one radially extending portion desirably with respect to the path of the charged particle beam and optionally two radially extending portions that face each other.

Further clause 4. The manipulator of any of further clauses 1 to 3, wherein the electrically insulating region is configured to electrically isolate a region configured to operate at a local ground potential and, optionally, the local ground potential is a radially inward facing surface desirably with respect to the path of the charged particle beam.

Further clause 5. The manipulator of any of further clauses 1 to 4, wherein the recess comprises a stem portion and a substantially angled, desirably tangential, portion, desirably with respect to the path of the charged particle beam.

Further clause 6. The manipulator of further clause 5 wherein the recess comprises two angled portions at a distal end of the stem portion, desirably at least one of the angled portions is a tangential portion that is desirably tangential with respect to the path.

Further clause 7. The manipulator of further clause 5 or 6, wherein the angled portion comprises a secondary portion, the secondary portion being angled towards a more proximate electrode of the plurality of electrodes, desirably the secondary portion is orthogonal to the angled portion, desirably the secondary portion is parallel to the stem portion.

Further clause 8. The manipulator of any of further clauses 5 to 7, wherein the insulating region defines a surface of the substantially tangential portion extending between the major surfaces, desirably the insulating region defines a surface of the secondary portion extending between the major surfaces.

Further clause 9. The manipulator according to further clause 8, wherein the electrodes surfaces that define the insulating region extend into the tangential portion desirably the secondary portion.

Further clause 10. The manipulator of any of further clauses 5 to 9, wherein the electrically insulating region is a surface of the tangential portion, desirably with respect to the path of the charged particle beam, that is distal from the stem portion such that the insulating region is shielded from the stem portion.

Further clause 11. The manipulator of any of further clauses 1 to 10, wherein the recessed surface comprises an end portion extending radially inwardly, desirably with respect to the path of the charged particle beam.

Further clause 12. The manipulator of any of further clauses 1 to 11, wherein the recessed surface comprises a region between the adjacent electrodes configured to operate at a local ground potential, desirably the local ground potential at least ends in an angled portion, the angled portion being angled with respect a radial direction from the path of the charged particle beam, desirably the local ground potential is within the angled portion, desirably the angled portion comprises a secondary portion.

Further clause 13. The manipulator of any of further clauses 1 to 12, wherein the recess extends further radially outward from the path of the charged particle beam than the adjacent electrodes,

Further clause 14. The manipulator of any of further clauses 1 to 13, wherein the electrodes comprise electrode surfaces that at least comprise respective portions of the inner wall and of the surface of the recess,

Further clause 15. The manipulator of further clause 14, wherein the recess extends radially further with respect to the path than at least one of the electrode surfaces of the adjacent electrodes.

Further clause 16. The manipulator of further clause 14 or 15, wherein the recess comprises outward electrode surfaces of the adjacent electrodes, the outward electrode surfaces extending radially outward with respect the path of the charged particle beam and/or the adjacent electrodes comprise outward electrode surface with respect to the path of the charged particle beam.

Further clause 17. The manipulator of any of further clauses 14 to 16, wherein the recess comprises a distal inward electrode surface of at least one of the electrode surfaces of the adjacent electrodes, the distal inward electrode surface being radially outward of the inner wall with respect to the path and/or the at least one of the electrode comprises a distal inward electrode surface radially outward of the inner wall with respect to the path of the charged particle beam.

Further clause 18. The manipulator of any of further clauses 14 to 16, wherein the recess at least one of the electrode comprises a radially outward facing surface for example with respect to the path of the charged particle beam, desirably the outward surface comprises the radially outward facing surface for example with respect to the charged particle beam,

Further clause 19. The manipulator according to any preceding further clause, the electrodes comprising a radially inwardly facing surface with respect the path of the charged particle beam that defines the inner wall, desirably the at least one of the electrode surfaces comprises an inward surface, desirably with respect to the path of the charged particle beam.

Further clause 20. The manipulator according to further clause 19, wherein at least one of the radially inwardly facing surfaces comprising a curved surface, desirably the radially inwardly facing surface of the electrodes.

Further clause 21. The manipulator according to any preceding further clause, wherein the electrically insulating region is configured to electrically insulate between the adjacent electrodes, desirably between adjoining (or adjacent) outward electrode surfaces.

Further clause 22. The manipulator according to any preceding further clause, wherein the substrate is silicon, each electrode is doped silicon and each electrically insulating region is silicon oxide.

Further clause 23. A manipulator array comprising an array of manipulators of any of further clauses 1 to 22 wherein the substrate of at least some desirably all the manipulators is the same and the charged particle beam manipulated by each manipulator is a sub-beam of a multi-beam or a plurality of sub-beams.

Further clause 24. A manipulator array for manipulating a plurality of charged particle beams along corresponding to a manipulator of the manipulator array, the manipulator array comprising a (planar) substrate with major surfaces and a plurality of manipulators arrayed in an array, each manipulator through which is defined a through-passage that defines associated apertures of the end of the through-passage in the major surfaces, the through passage configured for passage of a path of a charged particle sub-beam (of the plurality of charged particle beams), an inner wall of the through-passage between the major surfaces comprising a plurality of electrodes configured to manipulate the charged particle beam, each electrode comprising doped substrate, the through-passage further defining a plurality of recesses each between adjoining (or adjacent) electrodes and that extends away from the path of the charged particle sub-beam (optionally a central axis of the through-passage) for isolating the adjoining (or adjacent) electrodes, each recess being between the adjacent electrodes (desirably defining a gap or slot, desirably defined by recessed surfaces with respect to the inner wall) (preferably the doped surface of adjacent electrodes, the adjacent electrodes desirably defining a gap or slot, desirably defined by recessed surfaces with respect to the inner wall) and further comprising an electrically insulating region between the adjacent electrodes, wherein the recess extends behind at least one of the adjacent electrodes relative to the path of the charged particle sub-beam and comprising at least part of the electrically insulating region, desirably all of the insulating region; or a manipulator array for manipulating a plurality of charged particle sub-beams each corresponding to a manipulator of the manipulator array, the manipulator array comprising: a substrate with major surfaces and a plurality of manipulators arrayed in an array, through each manipulator is defined a through-passage with ends that define in the major surfaces associated apertures, the through passage is configured for passage of a path of a charged particle sub-beam, an inner wall of the through-passage between the major surfaces comprising a plurality of electrodes configured to manipulate the charged particle beam, each electrode comprising doped substrate, the through-passage further defining a plurality of recesses, each recess between adjacent electrodes and each recess extending away from the path of the charged particle sub-beam for isolating the adjacent electrodes, each recess being between the adjacent electrodes and comprising an electrically insulating region between the adjacent electrodes, wherein the recess extends behind at least one of the adjacent electrodes relative to the path of the charged particle sub-beam and comprises at least part of the electrically insulating region, desirably behind at least one of the adjacent electrodes.

Further clause 25. The manipulator array of further clause 24, wherein the electrically insulating region comprises a radially outward facing portion, desirably with respect to the path of the charged particle beam.

Further clause 26. The manipulator array of further clause 24 or 25, wherein the electrically insulating region comprises at least one radially extending portion desirably with respect to the path of the charged particle sub-beam and optionally two radially extending portions that face each other.

Further clause 27. The manipulator array of any of further clauses 24 to 26, wherein the electrically insulating region is configured to electrically isolate a region configured to operate at a local ground potential and, optionally, the local ground potential is a radially inward facing surface desirably with respect to the path of the charged particle beam.

Further clause 28. The manipulator array of any of further clauses 24 to 27, wherein the recess comprises a stem portion and a substantially angled, desirably tangential, portion, desirably with respect to the path of the charged particle beam.

Further clause 29. The manipulator array of further clause 28, wherein the recess comprises two angled portions at a distal end of the stem portion, desirably at least one of the angled portions is a tangential portion with respect to the path.

Further clause 30. The manipulator array of further clause 28 or 29, wherein the angled portion comprises a secondary portion, the secondary portion being angled towards a more proximate electrode of the plurality of electrodes, desirably the secondary portion is orthogonal to the angled portion, desirably the secondary portion is parallel to the stem portion.

Further clause 31. The manipulator array of any of further clauses 28 to 30, wherein the insulating region defines a surface of the substantially tangential portion extending between the major surfaces, desirably the insulating region defines a surface of the secondary portion extending between the major surfaces.

Further clause 32. The manipulator array of further clause 31, wherein the electrodes surfaces that define the insulating region extend into the tangential portion desirably the secondary portion. Further clause 33. The manipulator array of any of further clauses 28 to 32, wherein the electrically insulating region is a surface of the tangential portion, desirably with respect to the path of the charged particle beam, that is distal from the stem portion such that the insulating region is shielded from the stem portion.

Further clause 34. The manipulator array of any of further clauses 24 to 33, wherein the recessed surface comprises an end portion extending radially inwardly, desirably with respect to the path of the charged particle beam.

Further clause 35. The manipulator array of any of further clauses 24 to 34, wherein the recessed surface comprises a region between the adjacent electrodes configured to operate at a local ground potential, desirably the local ground potential at least ends in an angled portion, the angled portion being angled with respect a radial direction from the path of the charged particle beam, desirably the local ground potential is within the angled portion, desirably the angled portion comprises a secondary portion.

Further clause 36. The manipulator any of any of further clauses 24 to 35, wherein the recess extends further radially outward from the path of the charged particle beam than the adjacent electrodes,

Further clause 37. The manipulator any of any of further clauses 23 to 35, wherein the electrodes comprise electrode surfaces that at least comprise respective portions of the inner wall and of the surface of the recess,

Further clause 38. The manipulator array further clause 37, wherein the recess extends radially further than at least one of the electrode surfaces of the adjacent electrodes.

Further clause 39. The manipulator array of any of further clause 37 or 38, wherein the recess comprises outward electrode surfaces of the adjacent electrodes, the outward electrode surfaces extending radially outward with respect the path of the charged particle sub-beam and/or the adjacent electrodes comprise outward electrode surface with respect to the path of the charged particle beam.

Further clause 40. The manipulator array of any of further clauses 37 to 39, wherein the recess comprises a distal inward electrode surface of at least one of the electrode surfaces of the adjacent electrodes, the distal inward electrode surface being radially outward of the inner wall with respect to the path and/or the at least one of the electrode comprises a distal inward electrode surface radially outward of the inner wall with respect to the path of the charged particle beam.

Further clause 41. The manipulator array of any of further clauses 37 to 40, wherein the recess at least one of the electrode comprises a radially outward facing surface for example with respect to the path of the charged particle beam, desirably the outward surface comprises the radially outward facing surface for example with respect to the charged particle beam,

Further clause 42. The manipulator array of any of further clauses 37 to 41, the electrodes comprising a radially inwardly facing surface with respect the path of the charged particle sub-beam that defines the inner wall, desirably the at least one of the electrode surfaces comprises an inward surface, desirably with respect to the path of the charged particle beam.

Further clause 43. The manipulator array of further clause 42, the manipulator according to further clause 42, wherein at least one of the radially inwardly facing surfaces comprising a curved surface, desirably the radially inwardly facing surface of the electrodes.

Further clause 44. The manipulator array of any of further clauses 24 to 43, wherein the electrically insulating region is configured to electrically insulate between the separate adjacent electrodes between adjoining (or adjacent) outward electrode surfaces.

Further clause 45. The manipulator array of any of further clauses 24 to 44, wherein the substrate is silicon, each electrode is doped silicon and each electrically insulating region is silicon oxide.

Further clause 46. A charged particle column configured to project a charged particle beam towards a sample, the charged particle column comprising: A source configured to project a charged particle sub-beam towards a sample; and the manipulator of any of further clauses 1 to 22, the manipulator configured to manipulate the charged particle beam.

Further clause 47. A charged particle column of further clause 46 further comprising a multi-beam array configured to generate a multi-beam of charged particles from the charged particle beam and the manipulator is a manipulator array.

Further clause 48. A charged particle column of configured to project a multi-beam of charged particles towards a sample, the charged particle column comprising: a source configured to project a charged particle beam towards a sample; and the manipulator array of any of further clauses 24 to 45, the manipulator array configured to manipulate the charged particle-sub beam.

Further clause 49. A charged particle column of further clause 48 further comprising a multi-beam array configured to generate the sub-beams from the charged particle beam.

Further clause 50. A charged particle apparatus or tool comprising the charged particle column of any of further clauses 45 to 49 further a comprising a sample holder configured to support the sample.

It will be appreciated that the embodiments of the present disclosure are not limited to the exact construction that has been described above and illustrated in the accompanying drawings, and that various modifications and changes may be made without departing from the scope thereof. The present disclosure has been described in connection with various embodiments, other embodiments of the invention will be apparent to those skilled in the art from consideration of the specification and practice of the technology disclosed herein. It is intended that the specification and examples be considered as exemplary only, with a true scope and spirit of the invention being indicated by the following claims as well as the clauses and further clauses herein.

The descriptions above are intended to be illustrative, not limiting. Thus, it will be apparent to one skilled in the art that modifications may be made as described without departing from the scope of the claims set out below as well as the clauses and further clauses herein.

1. A manipulator array for manipulating a plurality of charged particle sub-beams each corresponding to a manipulator of the manipulator array, the manipulator array comprising:
a substrate with major surfaces and a plurality of manipulators arrayed in an array, through each manipulator is defined a through-passage with ends that define in the major surfaces associated apertures, the through passage is configured for passage of a path of a charged particle sub-beam, an inner wall of the through-passage between the major surfaces comprising a plurality of electrodes configured to manipulate the charged particle beam, each electrode comprising doped substrate, the through-passage further defining a plurality of recesses, each recess between adjacent electrodes and each recess extending away from the path of the charged particle sub-beam for isolating the adjacent electrodes, each recess being between the adjacent electrodes and comprising an electrically insulating region between the adjacent electrodes, wherein the recess extends behind at least one of the adjacent electrodes relative to the path of the charged particle sub-beam and comprises at least part of the electrically insulating region.

2. The manipulator array of claim 1, wherein at least part of the electrically insulating region extends behind one of the adjacent electrodes, desirably the electrically insulating region comprises a radially outward facing portion, desirably with respect to the path of the charged particle beam.

3. The manipulator array of claim 1, wherein the electrically insulating region comprises at least one radially extending portion.

4. The manipulator array of claim 1, wherein the electrically insulating region is configured to electrically isolate a region configured to operate at a local ground potential.

5. The manipulator array of claim 1, wherein the recess comprises a stem portion and a substantially angled portion with respect to the path of the charged particle beam.

6. The manipulator array of claim 5, wherein the electrically insulating region is a surface of a tangential portion.

7. The manipulator array of claim 1, wherein the recessed surface comprises an end portion extending radially inwardly.

8. The manipulator array of claim 1, wherein the recess extends further radially outward from the path of the charged particle beam than the adjacent electrodes.

9. The manipulator array of claim 1, wherein the electrodes comprise electrode surfaces that at least comprise respective portions of the inner wall and of the surface of the recess.

10. The manipulator array of claim 9, wherein the recess comprises outward electrode surfaces of the adjacent electrodes, the outward electrode surfaces extending radially outward with respect the path of the charged particle beam and/or the adjacent electrodes comprise outward electrode surface with respect to the path of the charged particle beam.

11. The manipulator array of claim 9, wherein the recess comprises a distal inward electrode surface of at least one of the electrode surfaces of the adjacent electrodes, the distal inward electrode surface being radially outward of the inner wall with respect to the path and/or the at least one of the electrode comprises a distal inward electrode surface radially outward of the inner wall with respect to the path of the charged particle beam.

12. The manipulator array of claim 9, wherein the recess at least one of the electrodes comprises a radially outward facing surface.

13. The manipulator array of claim 1, wherein the electrodes comprise a radially inwardly facing surface with respect to the path of the charged particle beam that defines the inner wall.

14. The manipulator array of claim 1, wherein the electrically insulating region is configured to electrically insulate between the adjacent electrodes.

15. A charged particle column of configured to project a multi-beam of charged particles towards a sample, the charged particle column comprising:
a source configured to project a charged particle beam towards a sample;
the manipulator array of claim 1, the manipulator array configured to manipulate charged particle-sub beam; and
a multi-beam array configured to generate the sub-beams from the charged particle beam.
